(19) United States
(12) Patent Application Publication
(10) Pub. No.: US 2025/0031410 A1
(43) Pub. Date: Jan. 23, 2025

(54) THIN FILM TRANSISTOR, METHOD FOR MANUFACTURING THE SAME AND DISPLAY APPARATUS COMPRISING THE SAME

(71) Applicant: LG Display Co., Ltd., Seoul (KR)

(72) Inventors: Dohyung LEE, Paju-si (KR); HongRak CHOI, Paju-si (KR); Dohyun KWAK, Paju-si (KR); JuHeyuck BAECK, Paju-si (KR)

(21) Appl. No.: 18/763,082

(22) Filed: Jul. 3, 2024

(30) Foreign Application Priority Data
Jul. 19, 2023 (KR) 10-2023-0093880

(51) Int. Cl. H01L 29/786; H01L 29/66; H10K 59/121; H10K 59/126

(52) U.S. Cl. CPC H01L 29/78633; H01L 29/6675; H01L 29/78696; H10K 59/1213; H10K 59/126

(57) ABSTRACT

A thin film transistor, and a method for manufacturing the same and a display apparatus comprising the same are provided. The thin film transistor includes a light shielding layer, an active layer on the light shielding layer, a gate electrode spaced apart from the active layer and overlapping at least a portion of the active layer, and an internal bridge electrically connecting the light shielding layer and the gate electrode being insulated from the active layer. The internal bridge overlaps the gate electrode and penetrates the active layer along a direction from the gate electrode to the light shielding layer. In addition, one embodiment of the present disclosure provides a display apparatus including the thin film transistor.

### CROSS-REFERENCE TO RELATED APPLICATIONS

This application claims the benefit and priority of the Korean Patent Application No. 10-2023-0093880 filed on Jul. 19, 2023, which is hereby incorporated by reference, for all purposes, as if fully set forth herein.

### BACKGROUND

### Technical Field

The present disclosure relates to a thin film transistor, a method for manufacturing the same, and a display apparatus including the same. More in detail, an embodiment of the present disclosure relates to a thin film transistor including an internal bridge connecting a gate electrode and a light shielding layer through a channel region, a method for manufacturing the same, and a display apparatus including the same.

### Description of the Related Art

Since a thin film transistor can be manufactured on a glass or plastic substrate, the thin film transistor has been widely used as a switching element or a driving element in a display apparatus such as a liquid crystal display apparatus or an organic light emitting device.

The thin film transistor may be categorized into an amorphous silicon thin film transistor in which amorphous silicon is used as an active layer, a polycrystalline silicon thin film transistor in which polycrystalline silicon is used as an active layer, and an oxide semiconductor thin film transistor in which oxide semiconductor is used as an active layer, based on a material constituting the active layer.

Among these, an oxide semiconductor thin film transistor (oxide semiconductor TFT), which has a high mobility and can have large resistance changes depending on the oxygen content, has an advantage in that desired properties may easily be obtained. In addition, the manufacturing cost of an oxide semiconductor thin film transistor is low because the oxide constituting the active layer can be formed at a relatively low temperature during the manufacturing process of the oxide semiconductor thin film transistor. Due to the nature of oxide, oxide semiconductor is transparent, thus the oxide semiconductor thin film transistor is advantageous for embodying transparent display apparatus.

### BRIEF SUMMARY

The electrical properties of oxide semiconductor can change depending on light. Therefore, in order to ensure driving stability of a thin film transistor including an oxide semiconductor, a light shielding layer for blocking light incident on the oxide semiconductor may be disposed in the thin film transistor. However, when a light shielding layer is disposed in a thin film transistor, the area of the thin film transistor may increase due to reasons such as the area of the light shielding layer itself and areas for forming of contact holes.

Meanwhile, light is blocked in the bezel portion, but in the case of a transparent display apparatus, light irradiated in an oblique direction may be incident on the bezel portion. Therefore, in the case of a transparent display apparatus, a light shielding layer needs to be disposed to protect the thin film transistor disposed in the bezel portion.

Because such thin film transistors as require a light shielding layer are placed in display apparatus, research is being conducted to improve the arrangement efficiency of the light shielding layer and to utilize the light shielding layer for driving the thin film transistor.

The present disclosure has been made in view of the above problems and it is an object of the present disclosure to improve an arrangement efficiency of the light shielding layer in a thin film transistor having a light shielding layer.

Various embodiments of the present disclosure provide a structure that can efficiently connect the light shielding layer and other devices in a thin film transistor having a light shielding layer.

Various embodiments of the present disclosure improve a driving efficiency of a thin film transistor by using a light shielding layer.

To this end, an embodiment of the present disclosure provides a thin film transistor including an internal bridge that penetrates the channel region and connects the gate electrode and the light shielding layer.

Another embodiment of the present disclosure provides a method of manufacturing a thin film transistor having the above structure.

Still another embodiment of the present disclosure provides a display apparatus including a thin film transistor having the above structure.

In accordance with an aspect of the present disclosure, the above and other objects can be accomplished by the provision of a thin film transistor comprising a light shielding layer, an active layer on the light shielding layer, a gate electrode spaced apart from the active layer and overlapping at least a portion of the active layer, and an internal bridge electrically connecting the gate electrode and the light shielding layer, wherein the active layer comprises a channel portion overlapping the gate electrode, a first connection portion contacting one side of the channel portion, the first connection portion not overlapping the gate electrode, and a second connection portion spaced apart from the first connection portion and contacting the other side of the channel portion, second connection portion not overlapping the gate electrode, wherein the light shielding layer overlaps at least the entire channel portion, and the internal bridge overlaps the gate electrode and penetrates the active layer along a direction from the gate electrode to the light shielding layer.

The thin film transistor may further comprise a buffer layer between the light shielding layer and the active layer and a gate insulating layer between the active layer and the gate electrode, wherein the internal bridge is insulated from the active layer and penetrates the gate insulating layer and the buffer layer.

The internal bridge may contact the gate electrode and the light shielding layer.

The internal bridge may be integrated with the gate electrode.

An active hole may be disposed in an area whose boundary is defined by the active layer, and the active layer is not disposed in the active hole, wherein at least a portion of the active hole overlaps the gate electrode, and the internal bridge is disposed in the active hole in a planar view.

The active hole as a whole may overlap the gate electrode.

A portion of the active hole may not overlap the gate electrode.

The active hole may include a first active hole and a second active hole spaced apart from each other, and at least a portion of the first active hole and at least a portion of the second active hole may overlap the gate electrode.

The internal bridge may comprise a first internal bridge disposed in the first active hole and a second internal bridge disposed in the second active hole.

The first active hole and the second active hole may be disposed to be spaced apart from each other along a direction perpendicular to a direction connecting the first connection portion and the second connection portion.

The first active hole and the second active hole may be disposed to be spaced apart from each other along a direction connecting the first connection portion and the second connection portion.

A portion of the active hole may protrude from the gate electrode along a direction connecting the first connection portion and the second connection portion in a plan view.

The active hole may protrude at both sides of the gate electrode in a plan view.

The thin film transistor may further comprise a first conductive pattern on the first connection portion and a second conductive pattern on the second connection portion, and wherein the first conductive pattern and the second conductive pattern do not overlap the gate electrode.

Each of the first conductive pattern and the second conductive pattern may not overlap the gate electrode.

Each of the first conductive pattern and the second conductive pattern may be spaced apart from the gate electrode in a plane view.

The active layer may include a first oxide semiconductor layer and a second oxide semiconductor layer on the first oxide semiconductor layer.

The thin film transistor may further comprise an external bridge not penetrating the active layer and being disposed outside the area defined by the active layer, wherein the external bridge may overlap the gate electrode and electrically connects the gate electrode and the light shielding layer.

The external bridge may be insulated from the active layer.

Another exemplary embodiment of the present disclosure provides a display apparatus comprising a substrate and a thin film transistor described above.

The display apparatus further may comprise a gate driver disposed on the substrate, wherein the gate driver may include the thin film transistor.

The display apparatus may further comprise a pixel driving circuit disposed on the substrate, wherein the pixel driving circuit may include the thin film transistor.

In accordance with other aspect of the present disclosure, the above and other objects can be accomplished by the provision of a method for manufacturing a thin film transistor, which comprises forming a light shielding layer on a substrate, forming a buffer layer on the light shielding layer, forming an active layer on the buffer layer, forming a gate insulating layer on the active layer and forming a gate electrode on the gate insulating layer, wherein forming the active layer includes forming an active hole by selectively removing a portion of the active layer, the active hole is disposed in an area whose boundary is defined by the active layer, forming the gate insulating layer includes forming a through hole penetrating the gate insulating layer and the buffer layer, the through hole passes through the active hole, and forming of the gate electrode includes forming an internal bridge disposed in the through hole.

The internal bridge may be in contact with the gate electrode and the light shielding layer.

### Technical Effects of the Disclosure

According to one embodiment of the present disclosure, the light shielding layer and the gate electrode are connected by an internal bridge disposed inside the active layer or an external bridge disposed outside the active layer, thereby providing the same effect as a thin film transistor having a double gate structure. As a result, the thin film transistor according to an embodiment of the present disclosure can have excellent current characteristics and excellent driving characteristics.

Since the internal bridge is disposed in an active hole formed in the active layer to electrically connect the gate electrode and the light shielding layer, an additional contact hole is not required to connect the gate electrode and the light shielding layer. As a result, the space utilization of the thin film transistor increases, and a thin film transistor with a double gate structure can be accomplished in a narrow area.

In addition, because the internal bridge or external bridge can apply an electric field to the channel portion of the active layer, the current characteristics of the channel portion can be improved.

A display apparatus according to an embodiment of the present disclosure includes the thin film transistor described above, and thus can exhibit excellent response speed and excellent display quality.

In addition to the effects mentioned above, other features and advantages of the present disclosure are described below, or can be clearly understood by those skilled in the art from the description.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other objects, features and other advantages of the present disclosure will be more clearly understood from the following detailed description taken in conjunction with the accompanying drawings, in which:

FIG. 1A is a plan view of a thin film transistor according to an embodiment of the present disclosure.

FIG. 1B is a cross-sectional view taken along line Ia-Ia′ of FIG. 1A.

FIG. 1C is a cross-sectional view taken along line Ib-Ib′ of FIG. 1A.

FIG. 2A and FIG. 2B are cross-sectional views of a thin film transistor according to another embodiment of the present disclosure, respectively.

FIG. 3A and FIG. 3B are cross-sectional views of a thin film transistor according to another embodiment of the present disclosure, respectively.

FIG. 4A is a plan view of a thin film transistor according to another embodiment of the present disclosure.

FIG. 4B is a cross-sectional view taken along line IVa-IVa′ of FIG. 4A.

FIG. 4C is a cross-sectional view taken along line IVb-IVb′ of FIG. 4A.

FIG. 5A and FIG. 5B are cross-sectional views of a thin film transistor according to another embodiment of the present disclosure, respectively.

FIG. 6 is a plan view of a thin film transistor according to another embodiment of the present disclosure.

FIG. 7A is a plan view of a thin film transistor according to another embodiment of the present disclosure.

FIG. 7B is a cross-sectional view taken along line VIIa-VIIa′ of FIG. 7A.

FIG. 7C is a cross-sectional view taken along line VIIb-VIIb′ of FIG. 7A.

FIG. 8 is a cross-sectional view of a thin film transistor according to another embodiment of the present disclosure.

FIG. 9 is a cross-sectional view of a thin film transistor according to another embodiment of the present disclosure.

FIG. 10A is a plan view of a thin film transistor according to another embodiment of the present disclosure.

FIG. 10B is a cross-sectional view taken along line Xa-Xa′ of FIG. 10A.

FIG. 10C is a cross-sectional view taken along line Xb-Xb′ of FIG. 10A.

FIG. 11 is a cross-sectional view of a thin film transistor according to another embodiment of the present disclosure.

FIG. 12A is a plan view of a thin film transistor according to another embodiment of the present disclosure.

FIG. 12B is a cross-sectional view taken along line XIIa-XIIa′ of FIG. 12A.

FIG. 12C is a cross-sectional view taken along line XIIb-XIIb′ of FIG. 12A.

FIG. 12D is a cross-sectional view taken along line XIIc-XIIc′ of FIG. 12A.

FIG. 13A is a plan view of a thin film transistor according to another embodiment of the present disclosure.

FIG. 13B is a cross-sectional view taken along line XIII-XIII′ of FIG. 13A.

FIGS. 14A, 14B, 14C, and 14D are plan views of a thin film transistor according to another embodiment of the present disclosure, respectively.

FIG. 15 is a plan view of a thin film transistor according to another embodiment of the present disclosure.

FIGS. 16A to 16F are schematic diagrams of a method for manufacturing a thin film transistor according to another embodiment of the present disclosure.

FIG. 17 is a schematic diagram of a display apparatus according to another embodiment of the present disclosure.

FIG. 18 is a schematic diagram of a shift register.

FIG. 19 is a circuit diagram of an embodiment of a stage provided in the shift register of FIG. 18.

FIG. 20 is a circuit diagram of a pixel of FIG. 17.

FIG. 21 is a circuit diagram of a pixel of a display apparatus according to another embodiment of the present disclosure.

FIG. 22 is a circuit diagram of a pixel of a display apparatus according to another embodiment of the present disclosure.

FIG. 23 is a circuit diagram of a pixel of a display apparatus according to another embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully explain the present disclosure to those skilled in the art.

A shape, a size, a dimension (e.g., length, width, height, thickness, radius, diameter, area, etc.), a ratio, an angle, and a number disclosed in the drawings for describing embodiments of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted.

In a case where ‘comprise,’ ‘have,’ and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜,’ ‘above˜,’ ‘below˜,’ and ‘next to˜,’ one or more portions may be arranged between two other portions unless ‘just’ or ‘direct’ is used.

Spatially relative terms such as “below,” “beneath,” “lower,” “above,” and “upper” may be used herein to easily describe a relationship of one element or elements to another element or elements as illustrated in the figures. It will be understood that these terms are intended to encompass different orientations of the device in addition to the orientation depicted in the figures. For example, if the device illustrated in the figure is reversed, the device described to be arranged “below,” or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to partition one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

In the drawings, the same or similar elements are denoted by the same reference numerals even though they are depicted in different drawings.

In the embodiments of the present disclosure, a source electrode and a drain electrode are distinguished from each other, for convenience of description. However, the source electrode and the drain electrode may be used interchangeably. The source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In some embodiments of the present disclosure, for convenience of explanation, a source connection part and a source electrode are distinguished, and a drain connection part and a drain electrode are distinguished, but the embodiments of the present disclosure are not limited thereto. The source connection may be a source electrode, and the drain connection may be a drain electrode. In addition, the source connection part may be a drain electrode, and the drain region may be a source electrode.

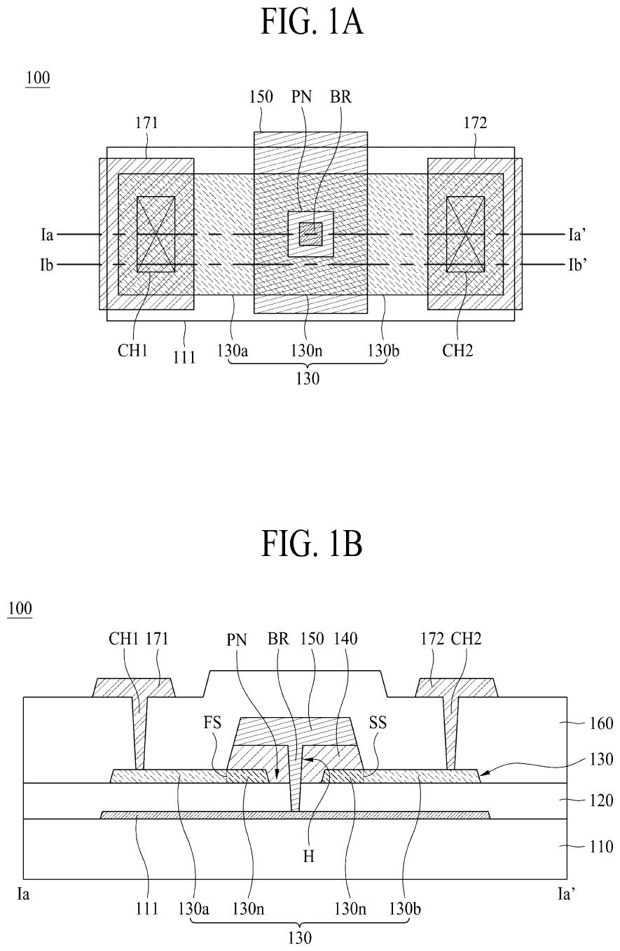

FIG. 1A is a plan view of a thin film transistor according to an embodiment of the present disclosure, FIG. 1B is a cross-sectional view taken along line Ia-Ia′ of FIG. 1A, and FIG. 1C is a cross-sectional view taken along line Ib-Ib′ of FIG. 1A.

The thin film transistor 100 according to an embodiment of the present disclosure includes a light shielding layer 111, an active layer 130 on the light shielding layer 111, a gate electrode 150 spaced apart from the active layer 130 and overlapping at least a portion of the active layer 130, and an internal bridge (BR) electrically connecting the gate electrode 150 and the light shielding layer 111. The internal bridge (BR) is insulated from the active layer 130.

Referring to FIGS. 1B and 1C, a thin film transistor 100 according to an embodiment of the present disclosure may be disposed on a substrate 110.

Glass or plastic may be used as the substrate 110. A transparent plastic with flexible properties, for example, polyimide, may be used as the plastic for substrate 110. When polyimide is used as the substrate 110, considering that a high temperature deposition process is performed on the substrate 110, heat-resistant polyimide that can withstand high temperatures may be used.

The light shielding layer 111 is disposed on the substrate 110. The light shielding layer 111 blocks light incident from the outside and protects the active layer 130. The light shielding layer 111 may be made of a material with light blocking properties.

In addition, according to an embodiment of the present disclosure, the light shielding layer 111 has electrical conductivity. The light shielding layer 111 according to an embodiment of the present disclosure may include a metal layer. The light shielding layer 111 may be made of one or more metal layers.

For example, the light shielding layer 111 may include at least one of aluminum (Al), silver (Ag), copper (Cu), molybdenum (Mo), chromium (Cr), tantalum (Ta), neodymium (Nd), and titanium (Ti). The light shielding layer 111 may have a single-layer structure or a multi-layer structure including at least two conductive layers with different physical or electrical properties.

A buffer layer 120 may be disposed on the light shielding layer 111. The buffer layer 120 has electrical insulation properties. The buffer layer 120 may include, for example, at least one of silicon oxide, silicon nitride, and metal-based oxide. The buffer layer 120 can block oxygen (O₂) or moisture (H₂O) to protect the active layer 130. In addition, the surface of the upper part of the substrate 110 can be made uniform by the buffer layer 120.

Referring to FIGS. 1B and 1C, the active layer 130 is disposed on the buffer layer 120.

The active layer 130 may include a semiconductor material. According to one embodiment of the present disclosure, the active layer 130 may include an oxide semiconductor material.

According to one embodiment of the present disclosure, the active layer 130 may include at least one of an IGZO (InGaZnO)-based oxide semiconductor material, a GZO (GaZnO)-based oxide semiconductor material, an IGO (InGaO)-based oxide semiconductor material, an IGZTO (InGaZnSnO)-based oxide semiconductor material, a GZTO (GaZnSnO)-based oxide semiconductor material, IZO (InZnO)-based oxide semiconductor material, ITZO (InSnZnO)-based oxide semiconductor material, ITO (InSnO)-based oxide semiconductor material, FIZO (FeInZnO)-based oxide semiconductor material, ZnO-based oxide semiconductor material, a SIZO (SiInZnO)-based oxide semiconductor material, and a ZnON (Zn-Oxynitride)-based oxide semiconductor material. However, one embodiment of the present disclosure is not limited thereto, and the active layer 130 may be formed of other oxide semiconductor materials known in the art.

According to one embodiment of the present disclosure, the active layer 130 includes a channel portion 130n, a first connection portion 130a, and a second connection portion 130b.

The channel portion 130n overlaps the gate electrode 150. The channel portion 130n serves as a channel for the thin film transistor 100.

According to one embodiment of the present disclosure, the light shielding layer 111 may overlap at least the entire channel portion 130n. As a result, the light shielding layer 111 can efficiently protect the channel portion 130n. Referring to FIG. 1A, based on a plan view, the light shielding layer 111 overlaps the entire channel portion 130n, and the area of the light shielding layer 111 is larger than the area of the channel portion 130n. According to one embodiment of the present disclosure, the light shielding layer 111 may overlap the entire active layer 130, and the area of the light shielding layer 111 may be larger than the area of the active layer 130.

The first connection portion 130a contacts one side (or a first side FS) of the channel portion 130n and does not overlap the gate electrode 150. The second connection portion 130b is spaced apart from the first connection portion 130a and contacts the other side (or a second side SS) of the channel portion 130n, and does not overlap the gate electrode 150. The first connection portion 130a and the second connection portion 130b may be called “connection portions.”

The first connection portion 130a and the second connection portion 130b may be formed by a selective conductorization of the active layer 130. The first connection portion 130a and the second connection portion 130b are also called “conductorized parts.”

According to one embodiment of the present disclosure, a process of imparting conductivity to a part of the oxide semiconductor layer is called conductorization. In addition, a process of imparting conductivity to a specific selected region of the oxide semiconductor layer is called selective conductorization. Through selective conductorization, parts to which conductivity is imparted become conductorized, and parts to which conductivity is not imparted are not conductorized. According to one embodiment of the present disclosure, a conductorized part may have a property similar to that of a metal or a conductor.

The first connection portion 130a and the second connection portion 130b shown in FIGS. 1A, 1B, and IC are parts provided with conductivity through selective conductorization.

According to one embodiment of the present disclosure, selective conductorization can be achieved by doping using a dopant. In addition, selective conductorization can be achieved through plasma treatment.

For example, selective conductorization of the active layer 130 may be achieved by a selective dopant doping or a selective dopant implantation using the gate electrode 150 or photoresist as a mask. The dopant may include, for example, at least one of boron (B), phosphorus (P), fluorine (F), and hydrogen (H).

When the selective conductorization of the active layer 130 is achieved by dopant doping, the dopant-doped region of the active layer 130 is selectively conductorized to become the first connection portion 130a or the second connection portion 130b. A region of the active layer 130 that is not doped with a dopant is not conductorized and may become a channel portion 130n.

Alternatively, selective conductorization of the active layer 130 may be achieved through a plasma processing applied in a process of patterning the gate insulating layer 140. For example, plasma may be used in the process of patterning the gate insulating layer 140, and the portion of the active layer 130 in contact with the plasma is selectively conductorized to become the first connection portion 130a or the second connection portion 130b of the active layer 130. A portion of the active layer 130 that is protected by the gate insulating layer 140 and gate electrode 150 and does not contact plasma is not conductorized and may become a channel portion 130n.

According to one embodiment of the present disclosure, the first connection portion 130a of the active layer 130 may be a source region, and the second connection portion 130b may be a drain region. However, one embodiment of the present disclosure is not limited thereto, and the first connection portion 130a may be a drain region and the second connection portion 130b may be a source region.

FIGS. 1B and 1C show a configuration in which the active layer 130 consists of one layer, but one embodiment of the present disclosure is not limited thereto. The active layer 130 may have a single-layer structure or a multi-layer structure.

Referring to FIGS. 1A and 1B, an active hole PN in which the active layer 130 is not disposed is disposed in an area whose boundary is defined by the active layer 130. Referring to FIGS. 1A and 1B, edge of the active hole PN may be defined by the active layer 130. According to one embodiment of the present disclosure, the active hole PN is disposed within an area defined by the active layer 130 in a plan view. According to one embodiment of the present disclosure, the active hole PN may be formed by removing a portion of the active layer 130 by patterning.

Referring to FIGS. 1A and 1B, an active hole PN is formed in an area of the active layer 130 and surrounded by the active layer 130. The active hole PN may be an area formed by removing a portion of the active layer 130. When referring to the plan view and cross-sectional view, the active hole PN is a hole formed in the active layer 130 by removing a part of the active layer 130, so according to an embodiment of the present disclosure, the hole formed in the active layer 130 is called an “active hole” (the active hole PN may also be referred to as a hole PN).

According to one embodiment of the present disclosure, at least a portion of the active hole PN may overlap the gate electrode 150. Referring to FIGS. 1A and 1B, the entire active hole PN may overlap the gate electrode 150.

A gate insulating layer 140 is disposed on the active layer 130. The gate insulating layer 140 protects the channel portion 130n.

The gate insulating layer 140 has insulating properties. The gate insulating layer 140 may include, for example, at least one of silicon oxide, silicon nitride, and metal-based oxide. The gate insulating layer 140 may have a single-layer structure or a multi-layer structure.

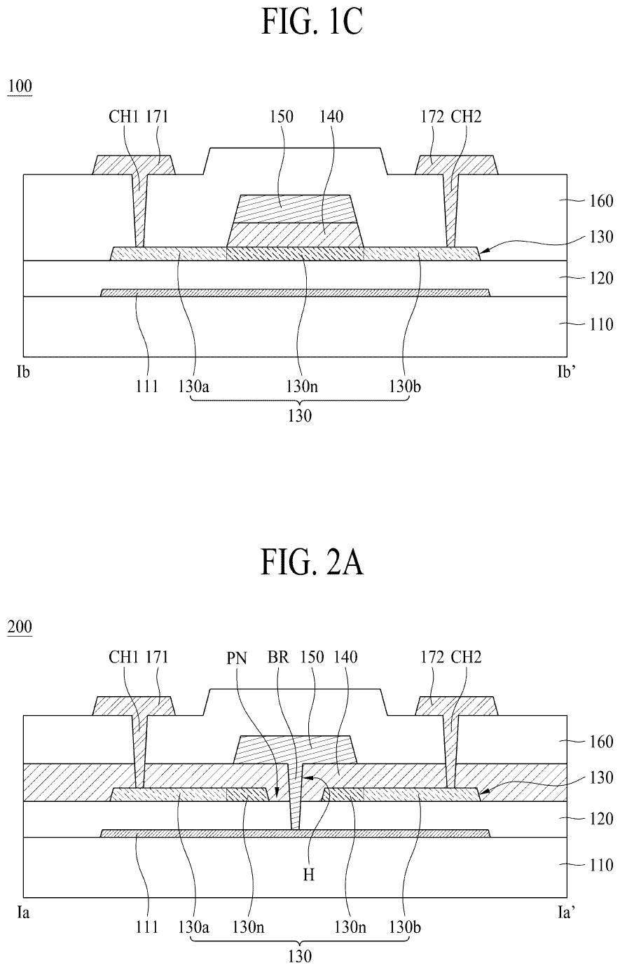

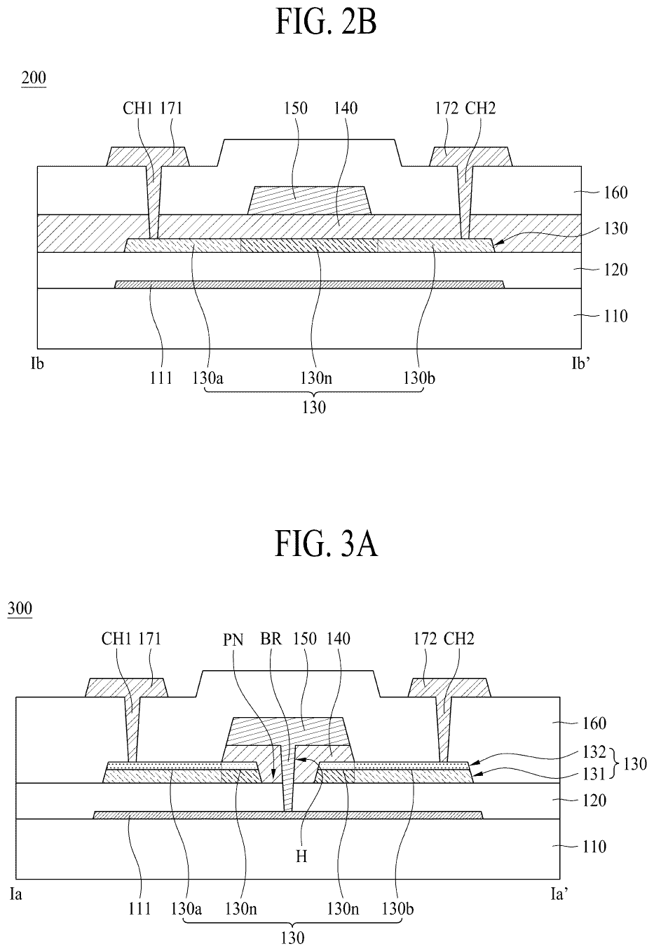

Referring to FIGS. 1B and 1C, the gate insulating layer 140 may have a patterned structure. However, the embodiment of the present disclosure is not limited thereto, and the gate insulating layer 140 may not be patterned or may be disposed on the entire surface above the substrate 110 (see FIGS. 2A and 2B).

The gate electrode 150 is disposed on the gate insulating layer 140. The gate electrode 150 overlaps the channel portion 130n of the active layer 130.

The gate electrode 150 may comprises at least one of an aluminum-based metal such as aluminum (Al) or an aluminum alloy, a silver-based metal such as silver (Ag) or a silver alloy, a copper-based metal such as copper (Cu) or a copper alloy, molybdenum-based metals such as molybdenum (Mo) or molybdenum alloy, chromium (Cr), tantalum (Ta), neodymium (Nd), and titanium (Ti). The gate electrode 150 may have a multi-layer structure including at least two conductive layers each having different physical properties. For example, the gate electrode 150 may include at least one of molybdenum (Mo) and titanium (Ti).

According to one embodiment of the present disclosure, the gate insulating layer 140 may be patterned by etching using the gate electrode 150 as a mask, and in this process, the active layer 130 may be selectively conductorized to form a first connection portion 130a and a second connection portion 130b. In detail, according to one embodiment of the present disclosure, a region of the active layer 130 that overlaps the gate electrode 150 is not conductorized and becomes a channel portion 130n having semiconductor characteristics, and regions of the active layer 130 that do not overlap the gate electrode 150 is conductorized to become the first connection portion 130a and the second connection portion 130b.

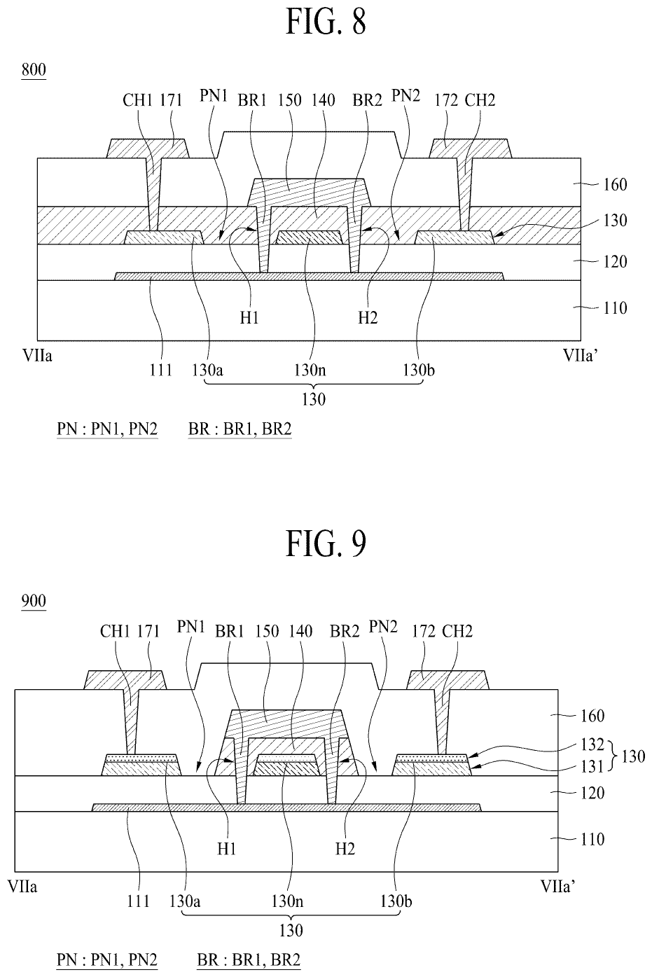

According to one embodiment of the present disclosure, the thin film transistor 100 includes an internal bridge BR. The internal bridge BR is insulated from the active layer 130 and electrically connects the gate electrode 150 and the light shielding layer 111. In some embodiments, the internal bridge BR may be referred to as a first internal bridge BR1 to distinguish from a second internal bridge BR2 shown in FIG. 8. The internal bridge BR extends from the gate electrode 150 and extends through the active hole PN of the active layer 130. As shown, the internal bridge BR extends through the active hole PN of the active layer 130 and electrically connects to the light shielding layer 111.

Referring to FIGS. 1A and 1B, the internal bridge BR overlaps the gate electrode 150 and penetrates the active layer 130 along a direction from the gate electrode 150 to the light shielding layer 111. In this structure, the internal bridge BR does not contact the active layer 130 and is insulated from the active layer 130. In addition, the internal bridge BR extends through the gate insulating layer 140 and the buffer layer 120. In some embodiments, as shown in FIG. 2A, the gate insulating layer 140 disposed such that the gate insulating layer 140 fully overlaps the active layer 130 and the light shielding layer 111 from a plan view.

According to one embodiment of the present disclosure, as shown in FIGS. 1A and 1B, the internal bridge BR may penetrate the gate insulating layer 140 and the buffer layer 120.

Referring to FIG. 1B, the internal bridge BR is disposed in the through hole H formed in the gate insulating layer 140 and the buffer layer 120. The internal bridge BR connects the gate electrode 150 and the light shielding layer 111 to each other through the through hole H formed in the gate insulating layer 140 and the buffer layer 120. The internal bridge BR may contact the gate insulating layer 140 and the buffer layer 120.

The internal bridge BR is disposed inside an area that overlaps the gate electrode 150 in a plan view. According to one embodiment of the present disclosure, the internal bridge BR may contact the gate electrode 150 and the light shielding layer 111.

In some embodiments, the light shielding layer 111 overlaps the channel portion 130n of the active layer 130 from a plan view. In particular, as shown in FIG. 2A, the light shielding layer 111 fully overlaps the channel portion 130n of the active layer 130 from a plan view. In other words, a length of the light shielding layer 111 is greater than a corresponding length of the channel portion 130n such that when seen from a plan view, the light shielding layer 111 fully overlaps the channel portion 130n.

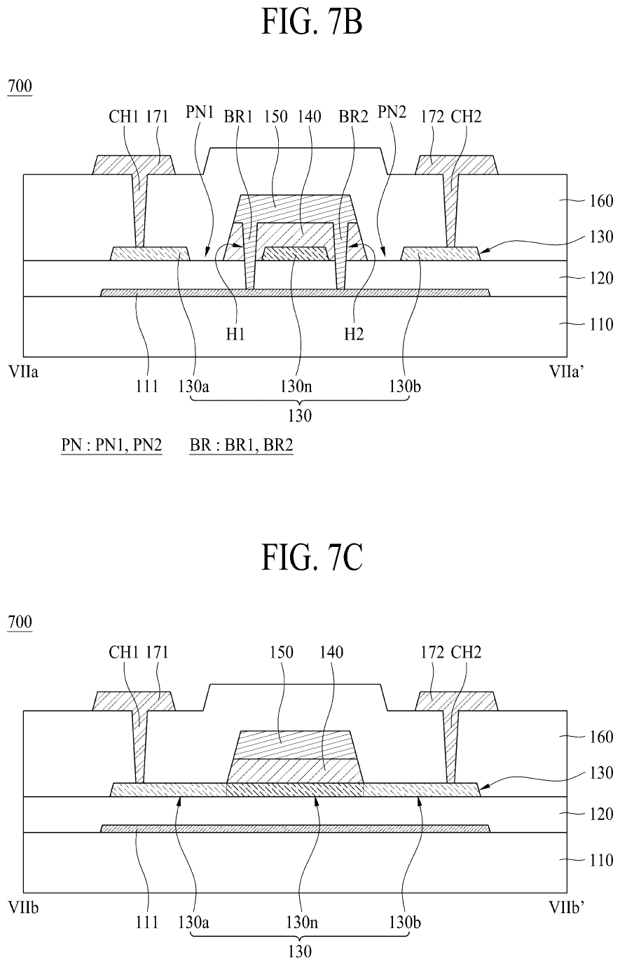

According to one embodiment of the present disclosure, the internal bridge BR may be formed integrally with the gate electrode 150. The internal bridge BR may be made of the same material as the gate electrode 150, and may be formed together with the gate electrode 150 when the gate electrode 150 is formed. For example, the internal bridge (BR shown in FIG. 2A or the first internal bridge BR1 shown in FIG. 7B) is integrated with the gate electrode 150 such that the internal bridge BR and the gate electrode 150 are a single, continuous structure. Similarly, the second internal bridge (BR2 shown in FIG. 7B) is integrated with the gate electrode 150 such that the second internal bridge BR2 and the gate electrode 150 are a single, continuous structure.

In addition, referring to FIGS. 1A and 1B, the internal bridge BR is disposed in the active hole PN in a plan view. The internal bridge BR penetrates the active hole PN. The internal bridge BR is disposed in the through hole H formed in the active hole PN in a plan view.

The light shielding layer 111 overlaps the channel portion 130n of the active layer 130, and the light shielding layer 111 is electrically connected to the gate electrode 150 by the internal bridge BR, thereby light shielding layer 111 may serve as a gate electrode of the thin film transistor 100. The gate electrode 150 and the light shielding layer 111 may function as a double gate on both sides of the channel portion 130n. As a result, the thin film transistor 100 according to one embodiment of the present disclosure can have a same effect as having a double gate structure.

Because of the effect of gate electrodes being disposed on both sides of the channel portion 130n, the thin film transistor 100 according to one embodiment of the present disclosure can have excellent current characteristics and excellent driving characteristics.

In addition, since the internal bridge BR is disposed in the active hole PN formed in the active layer 130 and electrically connects the gate electrode 150 and the light shielding layer 111, additional contact holes are not needed to connect the gate electrode 150 and the light shielding layer 111. In detail, the gate electrode 150 and the light shielding layer 111 can be connected to each other to exhibit a double gate effect even without a contact hole formed outside the active layer 130.

As a result, the space utilization of the thin film transistor 100 increases, and the thin film transistor 100 with a double gate structure can be formed in a narrow area.

The diameter of the internal bridge (BR) and the diameter of the active hole (PN) may vary depending on the performance of the etching equipment, the performance and resolution of the exposure equipment, or the like.

Since the internal bridge BR within the area of the active hole PN must be insulated from the active layer 130, the diameter of the active hole PN is designed to be larger than the diameter of the internal bridge BR. In order for the active hole PN to stably surround the internal bridge BR in a plan view and to insulate the internal bridge BR stably, the diameter of the active hole PN may be designed to be at least 4 μm larger than the diameter of the internal bridge BR. Alternatively, the diameter of the active hole (PN) may be designed to be at least 2 μm larger than the diameter of the internal bridge BR.

Considering the performance and resolution of the exposure equipment, the internal bridge BR may have a diameter of 1 μm or more, and may have a diameter of 2 μm or more.

Considering the width of the active layer 130 and the size of the channel portion 130n, the internal bridge BR may have a diameter of 2 μm to 4.5 μm.

Referring to FIGS. 1B and 1C, an interlayer insulating film 160 may be disposed on the gate electrode 150. The interlayer insulating film 160 may be made of an organic or inorganic insulating material. The interlayer insulating film 160 may have multi-layer structure having an organic layer and an inorganic layer.

According to one embodiment of the present disclosure, the thin film transistor 100 may include a source electrode 171 and a drain electrode 172 disposed on the interlayer insulating film 160. The positions of the source electrode 171 and the drain electrode 172 may be changed. However, one embodiment of the present disclosure is not limited thereto, and the first connection portion 130a and the second connection portion 130b may serve as a source electrode and a drain electrode, respectively.

Referring to FIGS. 1A, 1B, and IC, the source electrode 171 and the drain electrode 172 may be connected to the active layer 130 through contact holes CH1 and CH2, respectively. In detail, the source electrode 171 may contact the first connection portion 130a through the contact hole CH1. The drain electrode 172 may be spaced apart from the source electrode 171 and may contact the second connection portion 130b through the contact hole CH2.

FIGS. 2A and 2B are cross-sectional views of a thin film transistor 200 according to another embodiment of the present disclosure, respectively. FIG. 2A corresponds to a cross-sectional view taken along line Ia-Ia′ of FIG. 1A, and FIG. 2B corresponds to a cross-sectional view taken along line Ib-Ib′ of FIG. 1A.

The thin film transistor 200 of FIGS. 2A and 2B includes an unpatterned gate insulating layer 140. Different from the embodiment shown in FIGS. 1B and 1C, the gate insulating layer 140 of FIGS. 2A and 2B may not be patterned.

When the gate insulating layer 140 is not patterned, the active layer 130 may be selectively conductorized by a selective ion doping, a selective hydrogen implantation, or a selective ultraviolet irradiation, or the like, so that the first connection portion 130a and the second connection portion 130b can be formed.

Contact holes CH1 and CH2 may be formed in the gate insulating layer 140. In addition, a through hole H may be formed in the gate insulating layer 140 and the buffer layer 120, and the internal bridge BR may be disposed in the through hole H.

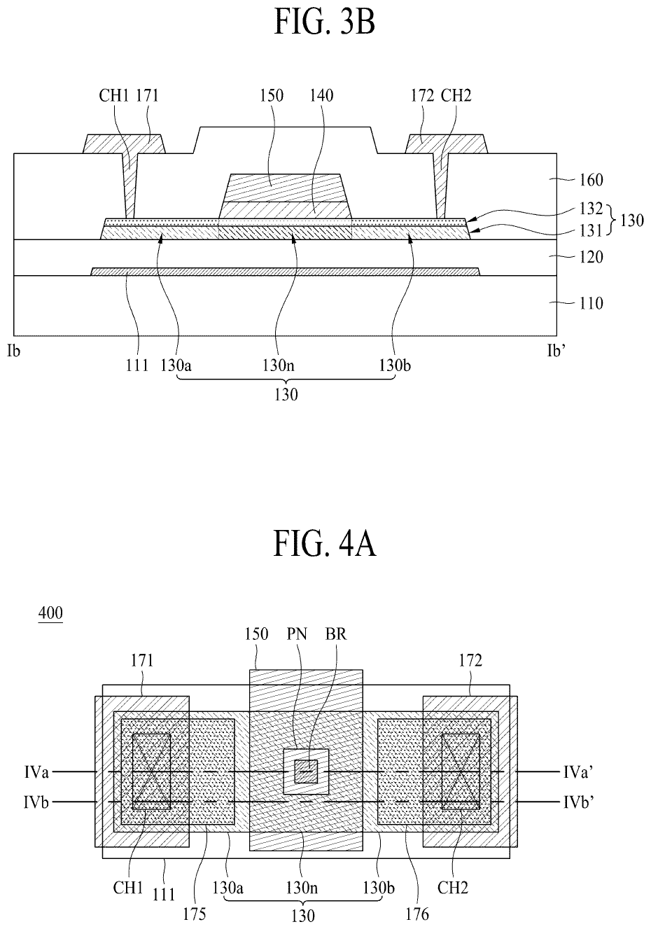

FIGS. 3A and 3B are cross-sectional views of a thin film transistor 300 according to another embodiment of the present disclosure, respectively. FIG. 3A corresponds to a cross-sectional view taken along line Ia-Ia′ of FIG. 1A, and FIG. 3B corresponds to a cross-sectional view taken along line Ib-Ib′ of FIG. 1A.

According to another embodiments of the present disclosure, the active layer 130 of the thin film transistor 300 may have a multilayer structure. Referring to FIGS. 3A and 3B, the active layer 130 may include a first oxide semiconductor layer 131 and a second oxide semiconductor layer 132 on the first oxide semiconductor layer 131.

The first oxide semiconductor layer 131 may support the second oxide semiconductor layer 132. Therefore, the first oxide semiconductor layer 131 can be referred to as a “support layer.” The channel may be mainly formed in the second oxide semiconductor layer 132. Accordingly, the second oxide semiconductor layer 132 may be referred to as a “channel layer.” However, the embodiment of the present disclosure is not limited thereto, and the channel may also be formed in the first oxide semiconductor layer 131. In addition, the channel may be formed mainly in the first oxide semiconductor layer 131.

The active layer 130 is composed of a first oxide semiconductor layer 131 and a second oxide semiconductor layer 132, and is also called to have a bi-layer structure.

Although not shown, the active layer 130 may have a structure of three or more layers. For example, the active layer 130 may include a first oxide semiconductor layer 131, a second oxide semiconductor layer 132 on the first oxide semiconductor layer 131, and a third oxide semiconductor layer on the second oxide semiconductor layer 132. However, another embodiment of the present disclosure is not limited thereto, and the active layer 130 may further include another semiconductor layer.

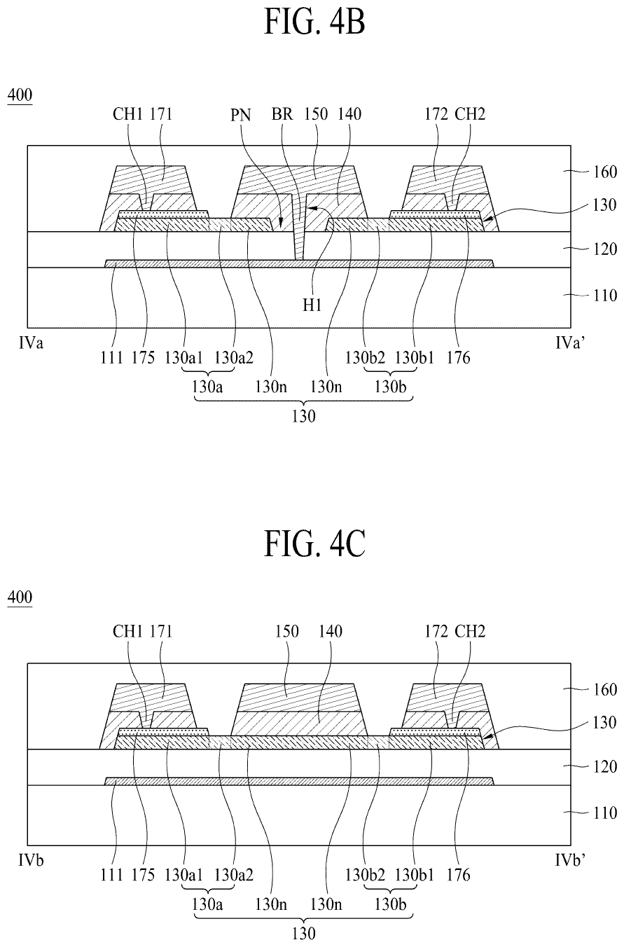

FIG. 4A is a plan view of a thin film transistor 400 according to another embodiment of the present disclosure, FIG. 4B is a cross-sectional view taken along IVa-IVa′ of FIG. 4A, and FIG. 4C is a cross-sectional view taken along IVb-IVb′ of FIG. 4A.

The thin film transistor 400 of FIGS. 4A, 4B, and 4C may include a first conductive pattern 175 on the first connection portion 130a and a second conductive pattern 176 on the second connection portion 130b.

According to another embodiment of the present disclosure, the first conductive pattern 175 and the second conductive pattern 176 may have electrical conductivity. The first conductive pattern 175 may be disposed in contact with the first connection portion 130a, and the second conductive pattern 176 may be disposed in contact with the second connection portion 130b.

For example, the first conductive pattern 175 and the second conductive pattern 176 may include metal. More in detail, the first conductive pattern 175 and the second conductive pattern 176 are formed of aluminum (Al), titanium (Ti), molybdenum (Mo), calcium (Ca), barium (Ba), and copper (Cu), or the like, respectively. The first conductive pattern 175 and the second conductive pattern 176 may have reducing properties.

In addition, the first conductive pattern 175 and the second conductive pattern 176 may include transparent conductive oxide (TCO). For example, each of the first conductive pattern 175 and the second conductive pattern 176 may include at least one of an ITO (InSnO)-based, an IGZO (InGaZnO)-based, an IGO (InGaO)-based, an IGZTO (InGaZnSnO)-based, an IZO (InZnO)-based, and an ITZO (InSnZnO)-based transparent conductive oxide (TCO).

Referring to FIGS. 4A, 4B, and 4C, the first conductive pattern 175 and the second conductive pattern 176 do not overlap the gate electrode 150, respectively. For example, the first conductive pattern 175 and the second conductive pattern 176 may be arranged to be spaced apart from the gate electrode 150 in a plan view.

The first connection portion 130a may include a first part 130a1 that overlaps the first conductive pattern 175 and a second part 130a2 that does not overlap the first conductive pattern 175.

The first part 130a1 of the first connection portion 130a that overlaps the first conductive pattern 175 is protected by the first conductive pattern 175 and may not be conductorized. In detail, in the process of selectively conductorizing the active layer 130, the first conductive pattern 175 acts as a mask for the first part 130a1 of the first connection portion 130a, and thus the first part 130a1 may maintain semiconductor properties without being conductorized. The first part 130a1 of the first connection portion 130a may contact the first conductive pattern 175.

The second part 130a2 of the first connection portion 130a that does not overlap the first conductive pattern 175 may be conductorized. In detail, in the process of selectively conductorizing the active layer 130, since there is no mask on the second part 130a2 of the first connection portion 130a, the second part 130a2 of the first connection portion 130a can be conductiorized.

The second connection portion 130b may include a first part 130b1 that overlaps the second conductive pattern 176 and a second part 130b2 that does not overlap the second conductive pattern 176.

The first part 130b1 of the second connection portion 130b that overlaps the second conductive pattern 176 is protected by the second conductive pattern 176 and may not be conductorized. In detail, in the process of selectively conductorizing the active layer 130, the second conductive pattern 176 acts as a mask for the first part 130b1 of the second connection portion 130b, and thus the first part 130b1 may maintain semiconductor properties without being conductorized. The first part 130b1 of the second connection portion 130b may contact the second conductive pattern 176.

The second part 130b2 of the second connection portion 130b that does not overlap the second conductive pattern 176 may be conductorized. In detail, in the process of selectively conductorizing the active layer 130, since there is no mask on the second part 130b2 of the second connection portion 130b, the second part 130b2 of the second connection portion 130b can be conductorized.

When the first part 130a1 of the first connection portion 130a and the first part 130b1 of the second connection portion 130b are in contact with the reducing metal, the first part 130a1 of the first connection portion 130a and the first part 130b1 of the second connection portion 130b can be respectively reduced, so that the electrical conductivity of the first part 130a1 of the first connection portion 130a and the first part 130b1 of the second connection portion 130b may be improved.

When the first part 130a1 of the first connection portion 130a and the first part 130b1 of the second connection portion 130b contact the first conductive pattern 175 and the second conductive pattern 176 including a metal layer, respectively, contact portions may be reduced and an oxygen vacancy may occur in the contact portions. Accordingly, electrical conductivity can be improved at the first part 130a1 and 130b1 to produce the same effect as conductorization. As a result, the electrical conductivity of the first part 130a1 of the first connection portion 130a and the first part 130b1 of the second connection portion 130b may be improved.

According to another embodiment of the present disclosure, the source electrode 171 and the drain electrode 172 may be disposed on the same layer as the gate electrode 150. In detail, as shown in FIGS. 4B and 4C, the source electrode 171 and the drain electrode 172 may be disposed on the gate insulating layer 140, like the gate electrode 150 is disposed on the gate insulating layer 140.

According to another embodiment of the present disclosure, the source electrode 171 may contact the first conductive pattern 175, and the drain electrode 172 may contact the second conductive pattern 176.

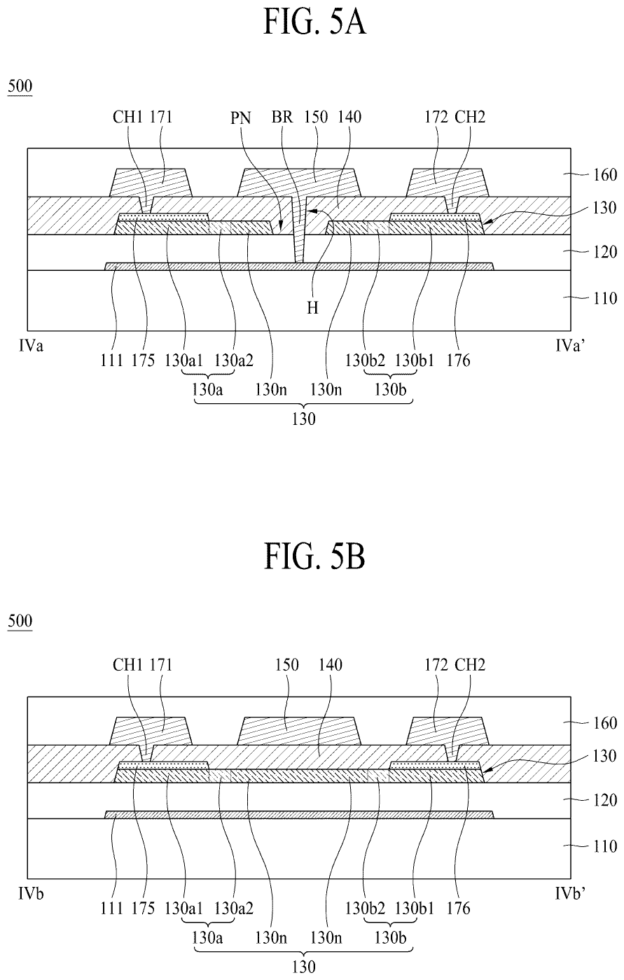

FIGS. 5A and 5B are cross-sectional views of a thin film transistor 500 according to another embodiment of the present disclosure, respectively. FIG. 5A corresponds to a cross-sectional view taken along IVa-IVa′ of FIG. 4A, and FIG. 5B corresponds to a cross-sectional view taken along IVb-IVb′ of FIG. 4A.

The thin film transistor 500 of FIGS. 5A and 5B includes an unpatterned gate insulating layer 140. When the gate insulating layer 140 is not patterned, the active layer 130 may be selectively conductorized by a selective ion doping, a selective hydrogen implantation, or a selective ultraviolet irradiation, or the like, so that the first connection portion 130a and the second connection portion 130b can be formed. In addition, contact holes CH1 and CH2 may be formed in the gate insulating layer 140.

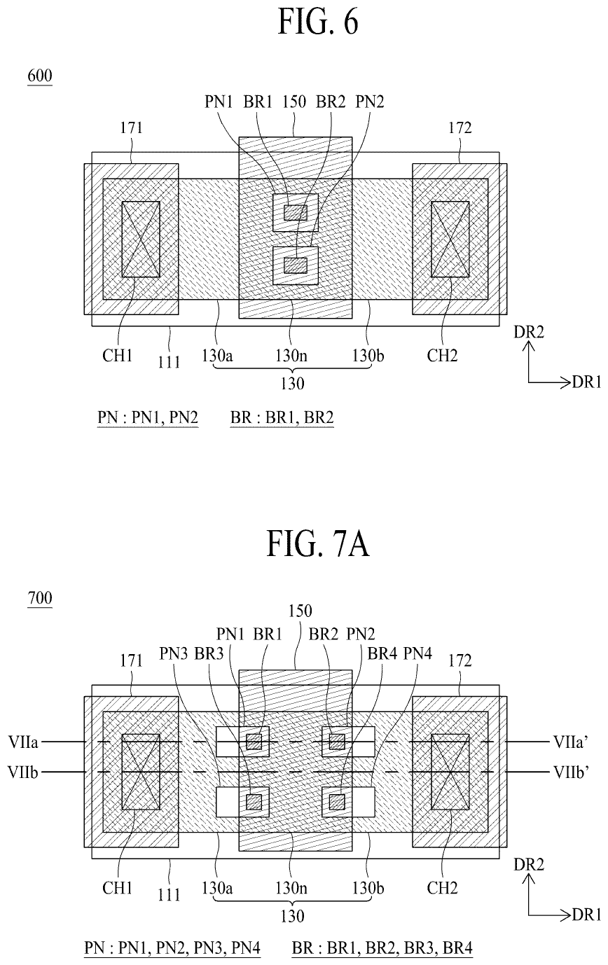

FIG. 6 is a plan view of a thin film transistor 600 according to another embodiment of the present disclosure. Referring to FIG. 6, the active hole PN may include two or more areas spaced apart from each other.

According to another embodiment of the present disclosure, the active hole PN may include a first active hole PN1 and a second active hole PN2 that are spaced apart from each other. At least a portion of the first active hole PN1 and at least a portion of the second active hole PN2 may overlap the gate electrode 150.

Referring to FIG. 6, the internal bridge BR may include two or more bridges. According to another embodiment of the present disclosure, the internal bridge BR includes a first internal bridge BR1 disposed in the first active hole PN1 and a second internal bridge BR2 disposed in the second active hole PN2. The first internal bridge BR1 and the second internal bridge BR2 each overlap the gate electrode 150. The first internal bridge BR1 and the second internal bridge BR2 may each be disposed in an area overlapping the gate electrode 150.

The first internal bridge BR1 is disposed in the first active hole PN1 in a plan view. The first internal bridge BR1 penetrates the first active hole PN1.

The second internal bridge BR2 is disposed in the second active hole PN2 in a plan view. The second internal bridge BR2 penetrates the second active hole PN2.

Referring to FIG. 6, the first active hole PN1 and the second active hole PN2 are aligned spaced apart from each other in a direction DR2 perpendicular to a direction DR1 connecting the first connection portion 130a and the second connection portion 130b. However, another embodiment of the present disclosure is not limited thereto, and the first active hole PN1 and the second active hole PN2 may be aligned spaced apart from each other in the direction DR1 connecting the first connection portion 130a and the second connection portion 130b.

Although not shown in the drawings, the first active hole PN1 and the second active hole PN2 may be aligned spaced apart from each other in a direction inclined at a predetermined angle with the direction DR1 connecting the first connection portion 130a and the second connection portion 130b.

For stable electrical connection between the gate electrode 150 and the light shielding layer 111, the thin film transistor 600 may have three or more active holes PN and three or more internal bridges BR. For example, the thin film transistor 600 may have 3 to 10 active holes PN and 3 to 10 internal bridges BR.

The size of the internal bridge BR and the active hole PN may vary depending on the performance and resolution of the exposure equipment. If the size of the internal bridge BR is reduced, the number of internal bridges BR may be increased to ensure stable electrical connection between the gate electrode 150 and the light shielding layer 111.

FIG. 7A is a plan view of a thin film transistor 700 according to another embodiment of the present disclosure, FIG. 7B is a cross-sectional view taken along VIIa-VIIa′ of FIG. 7A, and FIG. 7C is a cross-sectional view taken along VIIb-VIIb′ of FIG. 7A.

Referring to FIGS. 7A and 7B, active holes PN1, PN2, PN3 and PN4 are formed and a part of each active hole PN1, PN2, PN3 or PN4 may protrude from the gate electrode 150 along the direction DR1 connecting the first connection portion 130a and the second connection portion 130b in a plan view.

In detail, the first active hole PN1 and the third active hole PN3 each protrude from the gate electrode 150 in plan view, and protrude toward the first connection portion 130a. The second active hole PN2 and the fourth active hole PN4 each protrude from the gate electrode 150 in plan view, and protrude toward the second connection portion 130b.

As shown in FIGS. 7A and 7B, the active holes PN1, PN2, PN3, and PN4 may protrude on both sides of the gate electrode 150 in a plan view.

Referring to FIGS. 7A and 7B, the first active hole PN1, the second active hole PN2, the third active hole PN3, and the fourth active hole PN4 are spaced apart from each other.

The first active hole PN1 and the second active hole PN2 are arranged to be spaced apart from each other along the direction DR1 connecting the first connection portion 130a and the second connection portion 130b. In addition, the first active hole (PN1) and the third active hole (PN3) are arranged to be spaced apart from each other along a direction DR2 perpendicular to the direction DR1 connecting the first connection portion 130a and the second connection portion 130b.

The third active hole PN3 and the fourth active hole PN4 are arranged to be spaced apart from each other along the direction DR1 connecting the first connection portion 130a and the second connection portion 130b. In addition, the second active hole PN2 and the fourth active hole PN4 are arranged to be spaced apart from each other along a direction DR2 perpendicular to the direction DR1 connecting the first connection portion 130a and the second connection portion 130b.

At least a portion of the first active hole PN1 may overlap the gate electrode 150. Referring to FIG. 7A, a portion of the first active hole PN1 does not overlap the gate electrode 150.

The first internal bridge BR1 is disposed in the first active hole PN1 in a plan view. In detail, the first internal bridge BR1 is disposed in a region of the first active hole PN1 that overlaps the gate electrode 150 in a plan view. The first internal bridge BR1 penetrates the first active hole PN1 in an area overlapping with the gate electrode 150.

The first internal bridge BR1 is disposed in a through hole H1 penetrating the gate insulating layer 140 and the buffer layer 120, and electrically connects the gate electrode 150 and the light shielding layer 111.

At least a portion of the second active hole PN2 may overlap the gate electrode 150. Referring to FIG. 7A, a portion of the second active hole PN2 does not overlap the gate electrode 150.

The second internal bridge BR2 is disposed in the second active hole PN2 in a plan view. In detail, the second internal bridge BR2 is disposed in a region of the second active hole PN2 that overlaps the gate electrode 150 in a plan view. The second internal bridge BR2 penetrates the second active hole PN2 in an area overlapping with the gate electrode 150.

The second internal bridge BR2 is disposed in a through hole H2 penetrating the gate insulating layer 140 and the buffer layer 120, and electrically connects the gate electrode 150 and the light shielding layer 111.

At least a portion of the third active hole PN3 may overlap the gate electrode 150. Referring to FIG. 7A, a portion of the third active hole PN3 does not overlap the gate electrode 150.

The third internal bridge BR3 is disposed in the third active hole PN3 in a plan view. In detail, the third internal bridge BR3 is disposed in a region of the third active hole PN3 that overlaps the gate electrode 150 in plan view. The third internal bridge BR3 penetrates the third active hole PN3 in an area overlapping with the gate electrode 150.

The third internal bridge BR3 may be disposed in a through hole penetrating the gate insulating layer 140 and the buffer layer 120, and electrically connects the gate electrode 150 and the light shielding layer 111.

At least a portion of the fourth active hole PN4 may overlap the gate electrode 150. Referring to FIG. 7A, a portion of the fourth active hole PN4 does not overlap the gate electrode 150.

The fourth internal bridge BR4 is disposed in the fourth active hole PN4 in a plan view. In detail, the fourth internal bridge BR4 is disposed in a region of the fourth active hole PN4 that overlaps the gate electrode 150 in a plan view. The fourth internal bridge BR4 penetrates the fourth active hole PN4 in an area overlapping with the gate electrode 150.

The fourth internal bridge BR4 may be disposed in a through hole penetrating the gate insulating layer 140 and the buffer layer 120, and electrically connects the gate electrode 150 and the light shielding layer 111.

The first internal bridge BR1, the second internal bridge BR2, the third internal bridge BR3, and the fourth internal bridge BR4 are arranged to be spaced apart from each other. The first internal bridge BR1, the second internal bridge BR2, the third internal bridge BR3, and the fourth internal bridge BR4 penetrate the gate insulating layer 140 and the buffer layer 120, respectively.

According to another embodiment of the present disclosure, a gate voltage is applied to the light shielding layer 111 by a plurality of internal bridges BR1, BR2, BR3, and BR4. Accordingly, the thin film transistor 700 may have a double gate structure. In addition, since a gate voltage is applied to the plurality of internal bridges BR1, BR2, BR3, and BR4, the plurality of bridges BR1, BR2, BR3, and BR4 can also apply an electric field to the channel portion 130n. As a result, current characteristics of the thin film transistor 700 can be improved in the channel portion 130n of the thin film transistor 700.

In the thin film transistor 700 according to another embodiment of the present disclosure, since electric fields are applied to the channel portion 130n by the gate electrode 150, the light shielding layer 111, and the plurality of internal bridges BR1, BR2, BR3, and BR4, current characteristics of the channel portion 130n are improved, so that the thin film transistor 700 can have excellent driving characteristics.

According to one embodiment of the present disclosure, a distance between both ends of the channel portion 130n along the direction DR1 connecting the first connection portion 130a and the second connection portion 130b is defined as a length of the channel portion. A distance between both ends of the channel portion 130n along the direction DR2 perpendicular to the direction DR1 connecting the first connection portion 130a and the second connection portion 130b is defined as a width of the channel portion.

When the channel portion 130n has a large width, the interface between the channel portion 130n and the conductorized portion is large. Thus, when conductorization is performed to form the first connection portion 130a and the second connection portion 130b, diffusion of conductorization toward the channel portion 130n may be significantly. If the diffusion of the conductorization toward the channel portion 130n is large, the threshold voltage (Vth) of the thin film transistor 700 may move to the negative (−) direction, and the driving stability of the thin film transistor 700 may decreases.

On the other hand, when the channel portion 130n has a small width, the interface between the channel portion 130n and the conductorized portion is small. Thus, when conductorization is performed to form the first connection portion 130a and the second connection portion 130b, diffusion of conductorization toward the channel portion 130n can be suppressed.

According to another embodiment of the present disclosure, as shown in FIG. 7A, a first active hole PN1 and a third active hole PN3 are formed in a boundary between the channel portion 130n and the first connection portion 130a. As a result, the interface between the first connection portion 130a and the channel portion 130n is reduced, and diffusion of conductorization from the first connection portion 130a, which is a conductorized portion, toward the channel portion 130n can be suppressed.

In addition, as shown in FIG. 7A, the second active hole PN2 and the fourth active hole PN4 are formed in a boundary between the channel portion 130n and the second connection portion 130b. As a result, the interface between the second connection portion 130b and the channel portion 130n is reduced, and diffusion of conductorization from the second connection portion 130b, which is a conductorized portion, toward the channel portion 130n can be suppressed.

As a result, fluctuations or variation in the threshold voltage (Vth) of the thin film transistor 700 can be suppressed, and the driving stability of the thin film transistor 700 can be improved.

Meanwhile, when the overall width of the channel portion 130n is small, the total amount of carriers passing through the channel portion 130n of the thin film transistor 700 decreases, and the ON current characteristics of the thin film transistor 700 may deteriorate.

According to another embodiment of the present disclosure, the plurality of active holes PN1, PN2, PN3 and PN4 has the effect of dividing one channel portion 130n into multiple channels having smaller channel widths. As a result, even if the channel portion 130n has a large width, diffusion or penetration of conductorization toward the channel portion 130n can be suppressed, and it is possible to maintain the overall width of the channel portion 130n to be large, so that overall amount of carriers passing through 130n may not be substantially reduced. As a result, according to another embodiment of the present disclosure, the thin film transistor 700 can have excellent ON current characteristics, while diffusion or penetration of conductorization toward the channel portion 130n is suppressed.

FIG. 8 is a cross-sectional view of a thin film transistor 800 according to another embodiment of the present disclosure.

FIG. 8 corresponds to a cross-sectional view taken along line VIIa-VIIa′ in FIG. 7A. The thin film transistor 800 of FIG. 8 includes an unpatterned gate insulating layer 140. Different from the embodiment shown in FIGS. 7B and 7C, the gate insulating layer 140 may not be patterned as shown in FIG. 8.

FIG. 9 is a cross-sectional view of a thin film transistor 900 according to another embodiment of the present disclosure. FIG. 9 corresponds to a cross-sectional view taken along line VIIa-VIIa′ in FIG. 7A.

According to another embodiments of the present disclosure, the active layer 130 of the thin film transistor 900 may have a multilayer structure. Referring to FIG. 9, the active layer 130 may include a first oxide semiconductor layer 131 and a second oxide semiconductor layer 132 on the first oxide semiconductor layer 131. Although not shown in drawings, the active layer 130 may have a structure of three or more layers.

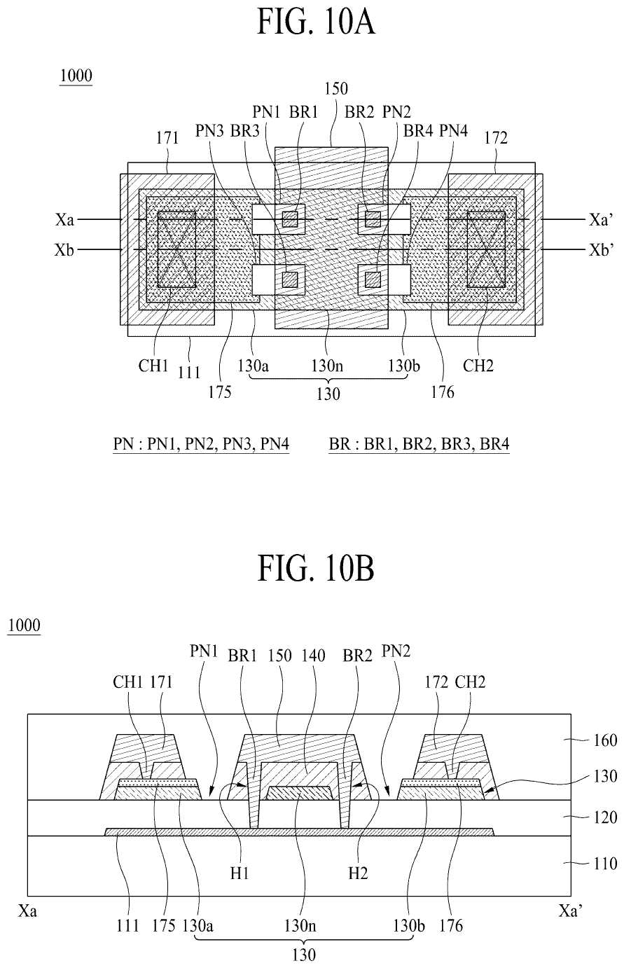

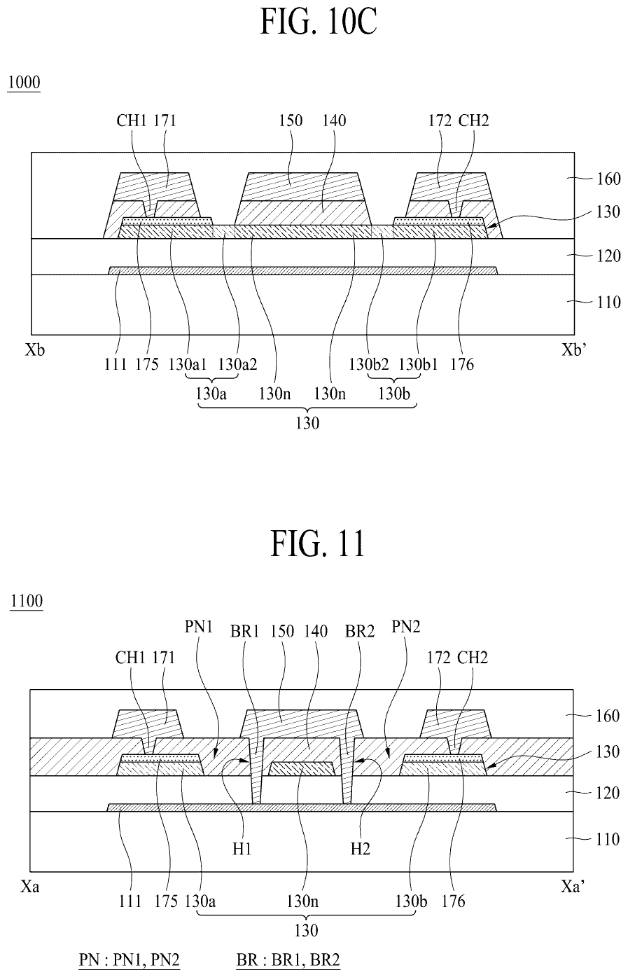

FIG. 10A is a plan view of a thin film transistor 1000 according to another embodiment of the present disclosure, FIG. 10B is a cross-sectional view taken along Xa-Xa′ of FIG. 10A, and FIG. 10C is a cross-sectional view taken along Xb-Xb′ of FIG. 10A.

Referring to FIGS. 10A, 10B, and 10C, the thin film transistor 1000 according to another embodiment of the present disclosure includes a first conductive pattern 175 on the first connection portion 130a and a second conductive pattern 176 on the second connection portion 130b.

According to another embodiment of the present disclosure, the first conductive pattern 175 and the second conductive pattern 176 may have electrical conductivity. The first conductive pattern 175 may be disposed in contact with the first connection portion 130a, and the second conductive pattern 176 may be disposed in contact with the second connection portion 130b. The conductive patterns 175 and 176 are not disposed in the active holes PN1, PN2, PN3, and PN4 where the active layer 130 is not disposed.

Since the first conductive pattern 175 and the second conductive pattern 176 have already been described, detailed descriptions of the first conductive pattern 175 and the second conductive pattern 176 will be omitted hereinafter to avoid redundancy.

The first connection portion 130a may include a first part 130a1 that overlaps the first conductive pattern 175 and a second part 130a2 that does not overlap the first conductive pattern 175.

The first part 130a1 of the first connection portion 130a that overlaps the first conductive pattern 175 is protected by the first conductive pattern 175 and may not be conductorized. The second part 130a2 of the first connection portion 130a that does not overlap the first conductive pattern 175 can be conductorized.

The second connection portion 130b may include a first part 130b1 that overlaps the second conductive pattern 176 and a second part 130b2 that does not overlap the second conductive pattern 176.

The first part 130b1 of the second connection portion 130b that overlaps the second conductive pattern 176 is protected by the second conductive pattern 176 and may not be conductorized. The second part 130b2 of the second connection portion 130b that does not overlap the second conductive pattern 176 can be conductorized.

According to another embodiment of the present disclosure, the source electrode 171 and the drain electrode 172 may be disposed on the same layer as the gate electrode 150. In detail, referring to FIGS. 10B and 10C, the source electrode 171 and the drain electrode 172 may be disposed on the gate insulating layer 140.

FIG. 11 is a cross-sectional view of a thin film transistor 1100 according to another embodiment of the present disclosure.

FIG. 11 corresponds to a cross-sectional view taken along Xa-Xa′ in FIG. 10A. The thin film transistor 1100 of FIG. 11 includes an unpatterned gate insulating layer 140.

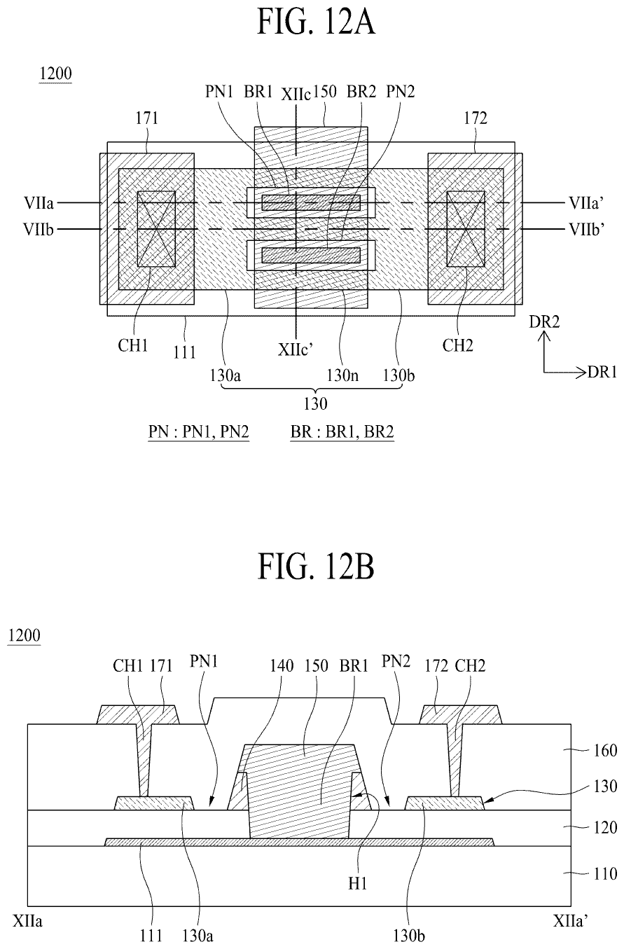

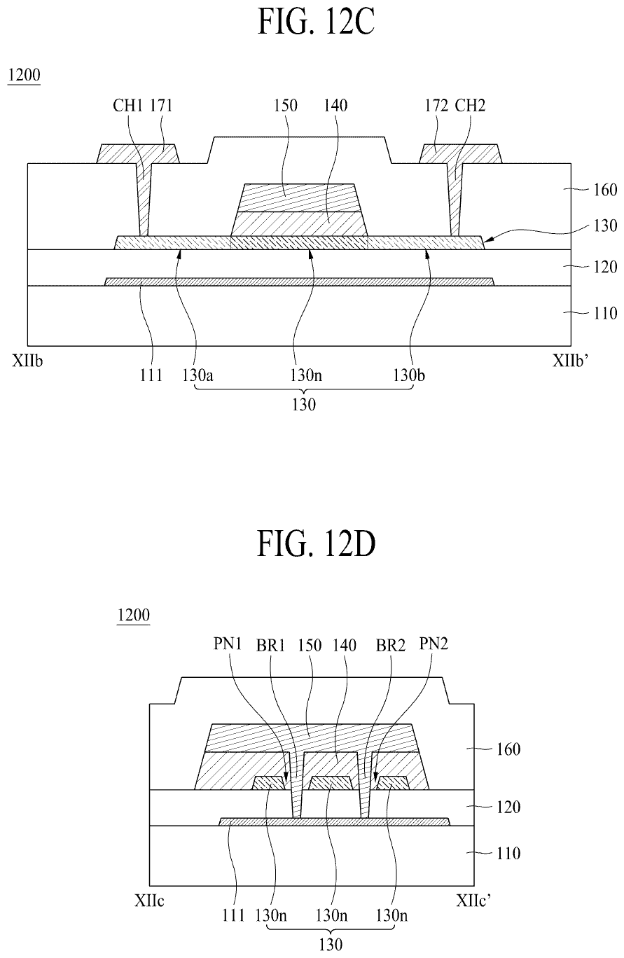

FIG. 12A is a plan view of a thin film transistor 1200 according to another embodiment of the present disclosure, FIG. 12B is a cross-sectional view taken along line XIIa-XIIa′ of FIG. 12A, FIG. 12C is a cross-sectional view taken along line XIIb-XIIb′ of FIG. 12A, and FIG. 12D is a cross-sectional view taken along line XIIc-XIIc′ of FIG. 12A.

The thin film transistor 1200 according to another embodiment of the present disclosure includes a first active hole PN1 and a second active hole PN2 spaced apart from each other. The first active hole PN1 and the second active hole PN2 may each protrude on both sides of the gate electrode 150 in a plan view.

Referring to FIG. 12A, a length of the first active hole PN1 and a length of the second active hole PN2 in the direction DR1 connecting the first connection portion 130a and the second connection portion 130b are longer than a length of the gate electrode 150 in the direction DR1 connecting the first connection portion 130a and the second connection portion 130b.

Referring to FIG. 12A, a first internal bridge BR1 is disposed in the first active hole PN1, and a second internal bridge BR2 is disposed in the second active hole PN2. The first internal bridge BR1 and the second internal bridge BR2 may each be disposed in an area overlapping the gate electrode 150.

The first internal bridge BR1 is disposed in a through hole H1 penetrating the gate insulating layer 140 and the buffer layer 120, and electrically connects the gate electrode 150 and the light shielding layer 111. In addition, the second internal bridge BR2 is disposed in a through hole H2 penetrating the gate insulating layer 140 and the buffer layer 120, and electrically connects the gate electrode 150 and the light shielding layer 111.

Referring to FIG. 12C, a area of the channel portion 130n disposed between the first internal bridge BR1 and the second internal bridge (BR2) has a structure surrounded by the gate electrode 150, the light shielding layer 111, the first internal bridge BR1 and the second internal bridge BR2. As a result, the electrical characteristics of the channel portion 130n may be improved in the area between the first internal bridge BR1 and the second internal bridge BR2. Accordingly, current characteristics of the entire channel portion 130n are improved, and the thin film transistor 1200 can have excellent driving or operating characteristics.

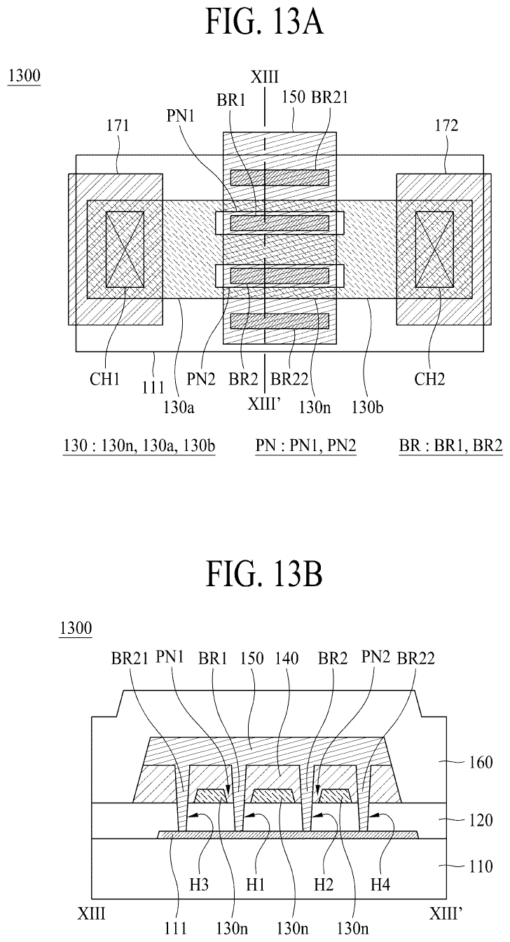

FIG. 13A is a plan view of a thin film transistor 1300 according to another embodiment of the present disclosure, and FIG. 13B is a cross-sectional view taken along line XIII-XIII′ of FIG. 13A.

Compared to the thin film transistor 1200 shown in FIG. 12A, the thin film transistor 1300 shown in FIG. 13A further includes external bridges BR21 and BR22. The external bridges BR21 and BR22 are disposed outside the area defined by the active layer 130 in a plan view.

Referring to FIG. 13A, the thin film transistor 1300 according to another embodiment of the present disclosure includes an external bridge BR21, BR22 that does not penetrate the active layer 130 and disposed outside the area defined by the active layer 130. The external bridge BR21, BR22 overlaps the gate electrode 150 and electrically connect the gate electrode 150 and the light shielding layer 111.

In detail, the external bridge may include a first external bridge BR21 and a second external bridge BR22. The first external bridge BR21 is disposed in a through hole H3 penetrating the gate insulating layer 140 and the buffer layer 120, and electrically connects the gate electrode 150 and the light shielding layer 111. The second external bridge BR22 is disposed in a through hole H4 penetrating the gate insulating layer 140 and the buffer layer 120, and electrically connects the gate electrode 150 and the light shielding layer 111.

The external bridges BR21 and BR22 are insulated from the active layer 130.

Referring to FIG. 13B, the four sides of the channel portion 130n are surrounded by the gate electrode 150, the light shielding layer 111, the first external bridge BR21, the first internal bridge BR1, the second internal bridge BR2 and the second external bridge BR22. As a result, when the gate voltage is applied, the electric field effect applied to the channel portion 130n is increased, and the electrical characteristics of the channel portion 130n can be improved. Accordingly, the current characteristics of the entire channel portion 130n are improved, and the thin film transistor 1300 can have excellent driving or operating characteristics.

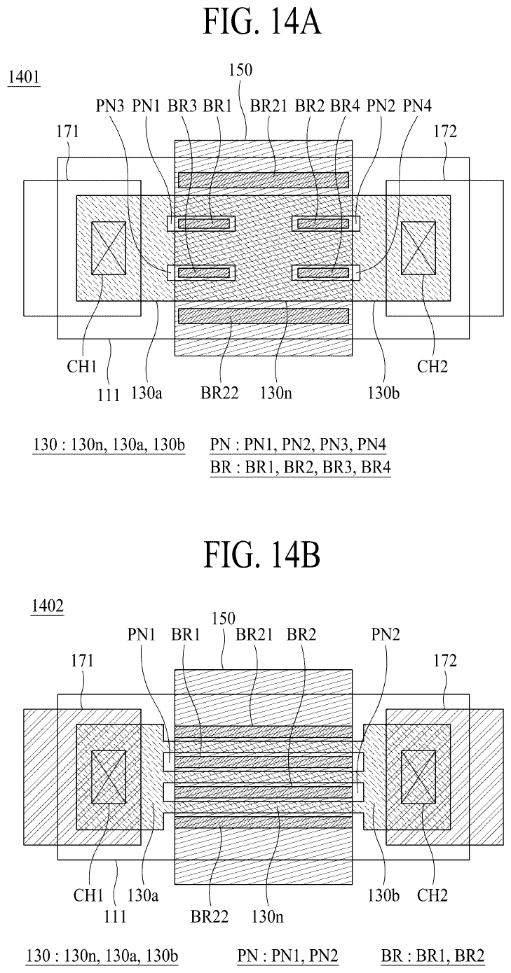

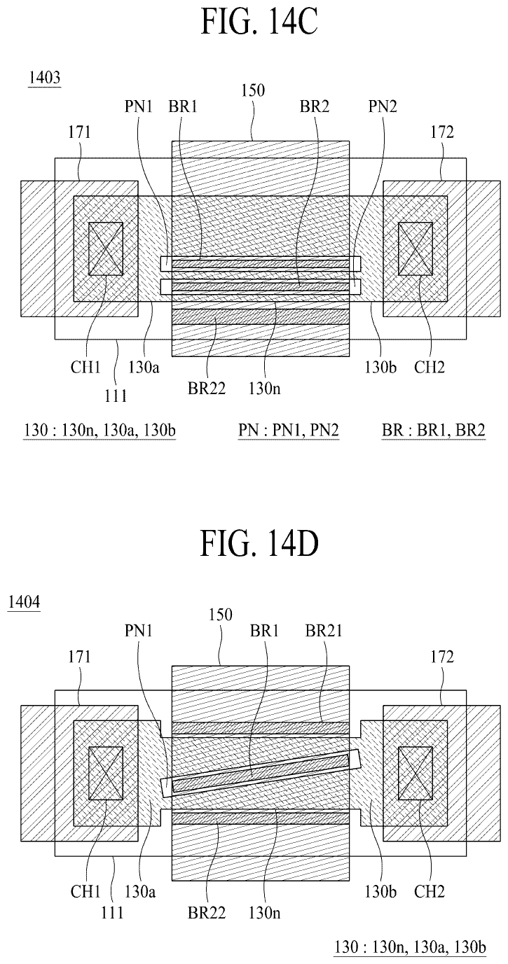

FIGS. 14A, 14B, 14C, and 14D are plan views of thin film transistors 1401, 1402, 1403, and 1404, respectively, according to another embodiment of the present disclosure.

The thin film transistor 1401 shown in FIG. 14A includes a first external bridge BR21, a second external bridge BR22, a first internal bridge BR1, a second internal bridge BR2, a third internal bridge BR3 and a fourth internal bridge BR4.

The thin film transistor 1402 shown in FIG. 14B has a structure in which the width of the channel portion 130n is smaller than the width of the first connection portion 130a and the width of the second connection portion 130b.

Referring to FIG. 14B, a part of the channel portion 130n at an edge in the width direction of the channel portion 130n is removed along the longitudinal direction of the channel portion 130n, which is the direction connecting the first connection portion 130a and the second connection portion 130b, thereby a width of the channel portion 130n reduced. The first external bridge BR21 and the second external bridge BR22 may be disposed in the area where the channel portion 130n has been removed.

The thin film transistor 1403 shown in FIG. 14C has a structure in which a first internal bridge BR1 and a second internal bridge BR2 are disposed biased to one side of the channel portion 130n in the width direction. Referring to FIG. 14C, the first internal bridge BR1 and the second internal bridge BR2 are disposed biased to one side of the channel portion 130n.

“When the thin film transistor 1403 shown in FIG. 14c is turned on, in a region channel portion 130n where the first inner bridge BR1 and the second inner bridge BR2 are disposed, the current increase rate is relatively fast, but the amount of charge is relatively small due to the narrow width. On the other hand, in a region channel portion 130n where the first internal bridge BR1 and the second internal bridge BR2 are not disposed, the current increase rate is relatively slow, but the amount of charge is large because the width is wide. Due to the deviations of current increase rate and charge amount in the channel portion 130n, the slope of the current graph of the thin film transistor 1403 may increase in the threshold voltage section. The thin film transistor 1403 with these characteristics may have a large s-factor (threshold swing).”

The thin film transistor 1404 shown in FIG. 14D includes a first internal bridge BR1 disposed diagonally along the width direction of the channel portion 130n.

In the above, various arrangement and shapes of the internal bridges BR1, BR2, BR3 and BR4 and external bridges BR21 and BR22 have been described as exemplary with reference to drawings, but embodiments of the present disclosure are not limited thereto. The internal bridges BR1, BR2, BR3 and BR4 and external bridges BR21 and BR22 may be arranged in various structures other than those shown in the drawings.

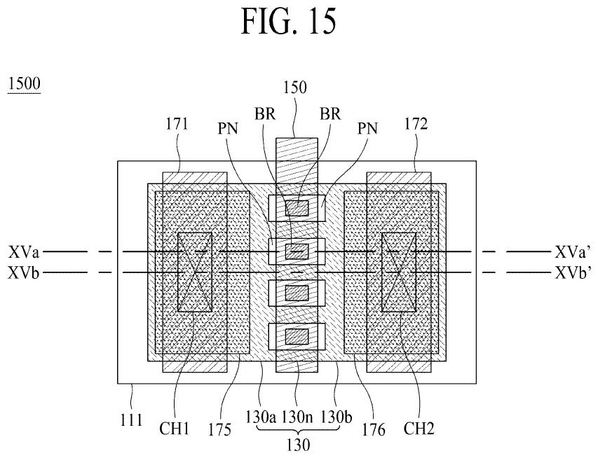

FIG. 15 is a plan view of a thin film transistor 1500 according to another embodiment of the present disclosure. The thin film transistor 1500 shown in FIG. 15 has a similar structure to the thin film transistor 1200 shown in FIG. 12A. However, the thin film transistor 1500 shown in FIG. 15 includes a larger number of active holes PN and internal bridges BR than the thin film transistor 1200 shown in FIG. 12A.

FIG. 15 shows a thin film transistor 1500 including four active holes PN and four internal bridges BR. However, another embodiment of the present disclosure is not limited thereto, and the thin film transistor may include a larger number of active holes PN and internal bridges BR.

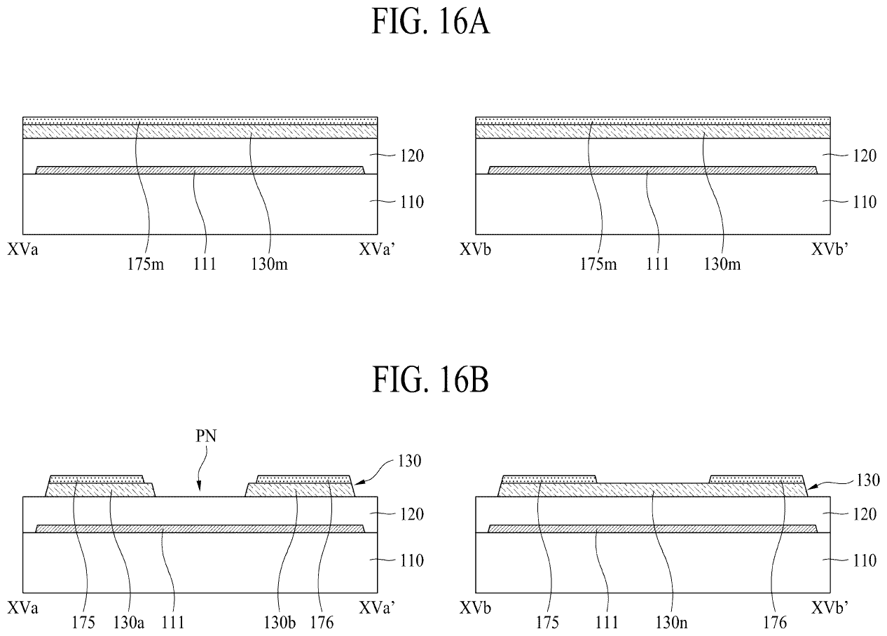

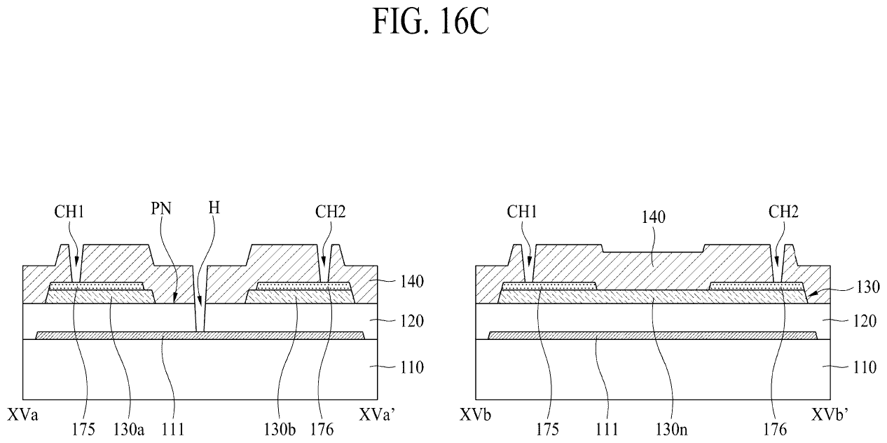

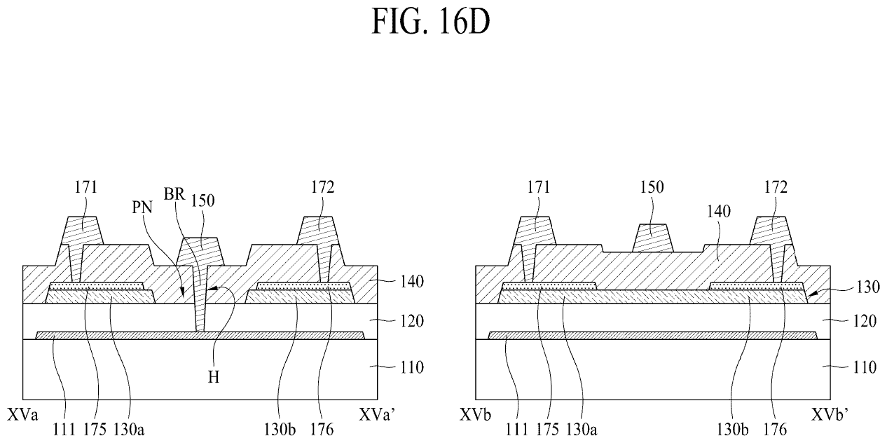

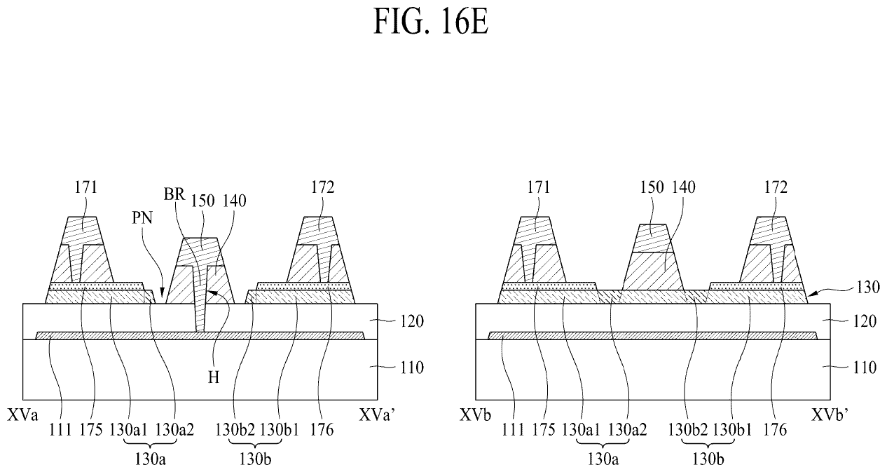

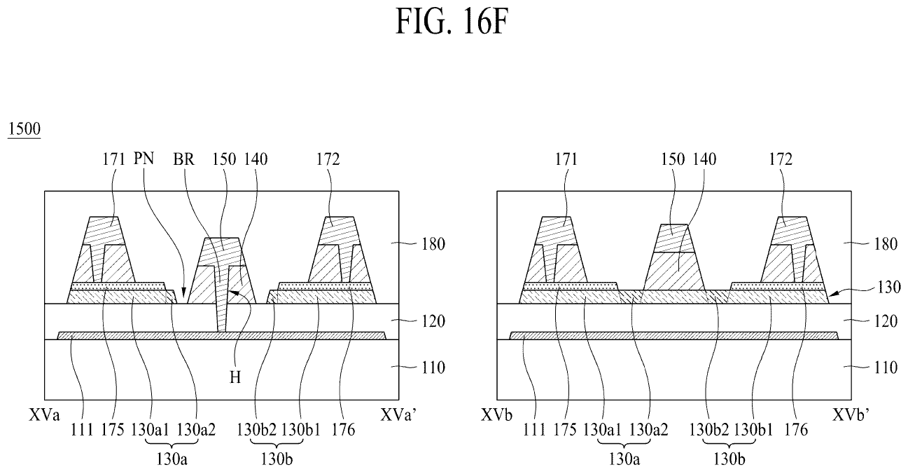

Hereinafter, a method of manufacturing a thin film transistor according to another embodiment of the present disclosure will be described with reference to FIGS. 16A to 16F.

FIG. 16A to 16F are schematic diagrams of a method of manufacturing a thin film transistor 1500 according to another embodiment of the present disclosure.

FIG. 16A to 16F show cross-sectional views taken along lines corresponding to XVa-XVa′ and XVb-XVb′ of FIG. 15.

The method of manufacturing a thin film transistor 1500 according to another embodiment of the present disclosure includes forming a light shielding layer 111 on a substrate 110, forming a buffer layer 120 on the light shielding layer 111, forming an active layer 130 on the buffer layer 120, forming a gate insulating layer 140 on the active layer 130, and forming a gate electrode 150 on the gate insulating layer 140.

First, referring to FIG. 16A, a light shielding layer 111 is formed on a substrate 110, and a buffer layer 120 is formed on the light shielding layer 111. In addition, an active material layer 130m is formed on the buffer layer 120. Referring to FIG. 16A, a conductive material layer 175m may be formed on the active material layer 130m.

Next, referring to FIG. 16B, the active material layer 130m is patterned to form an active layer 130. At this time, the conductive material layer 175m is patterned to form a first conductive pattern 175 and a second conductive pattern 176.

The active material layer 130m and the conductive material layer 175m may be patterned through a same process. For example, by selective patterning using a halftone mask, the active material layer 130m and the conductive material layer 175m are patterned in a same process, so that the active layer 130, the first conductive pattern 175, and the second conductive pattern 176 are formed.

The first conductive pattern 175 and the second conductive pattern 176 are disposed on the active layer 130. The entire conductive material layer 175m on the channel portion 130n of the active layer 130 may be removed. As a result, the first conductive pattern 175 or the second conductive pattern 176 may not be disposed on the channel portion 130n of the active layer 130.

In addition, in the step of forming the active layer 130, a portion of the active layer 130 is selectively removed to form an active hole PN. More in detail, during the formation of the active layer 130, a portion of the active material layer 130m disposed in the area whose edge is defined by the active layer 130 may be removed, thereby an active hole PN may be formed.

Referring to FIG. 15 and FIG. 16B, the active hole PN is disposed in an area whose edge is defined by the active layer 130.

Next, referring to FIG. 16C, a gate insulating layer 140 is formed on the active layer 130. The gate insulating layer 140 has insulating properties. The gate insulating layer 140 may be made of a dielectric material.

In the step of forming the gate insulating layer 140, a through hole H penetrating the gate insulating layer 140 and the buffer layer 120 is formed. The through hole H penetrates the active hole PN formed in an area whose edge is defined by the active layer 130. An upper part of the light shielding layer 111 is partially exposed by the through hole H. More in detail, a portion of the light shielding layer 111 may be exposed from the buffer layer 120 and the gate insulating layer 140 by the through hole H.

In addition, in the step of forming the gate insulating layer 140, contact holes CH1 and CH2 may be formed in the gate insulating layer 140. The upper part of the active layer 130 is partially exposed by the contact holes CH1 and CH2. More in detail, a portion of the first conductive pattern 175 disposed on the active layer 130 is exposed from the gate insulating layer 140 by the first contact hole CH1, and a portion of the second conductive pattern 176 disposed on the active layer 130 may be exposed from the gate insulating layer 140 by the second contact hole CH2.

Referring to FIG. 16D, a gate electrode 150 is formed on the gate insulating layer 140.

When the gate electrode 150 is formed, an internal bridge BR may be formed. According to another embodiment of the present disclosure, forming the gate electrode 150 may include forming the internal bridge BR.

The internal bridge BR is disposed in the through hole H. By disposing the gate electrode 150 forming material in the through hole H, an internal bridge BR can be formed. The internal bridge BR is in contact with the gate electrode 150 and the light shielding layer 111.

The internal bridge BR may be made of the same material as the gate electrode 150 and may be made through the same process as the gate electrode 150.

Referring to FIG. 16D, the source electrode 171 and the drain electrode 172 may also be formed on the gate insulating layer 140. According to another embodiment of the present disclosure, the source electrode 171 and the drain electrode 172 may be disposed on the same layer as the gate electrode 150.

According to another embodiment of the present disclosure, the source electrode 171 and the drain electrode 172 may be made of the same material as the gate electrode 150 and may be made by the same process as the gate electrode 150.

Referring to FIG. 16E, the gate insulating layer 140 is selectively etched. For example, the gate insulating layer 140 may be selectively etched by an etching process using the gate electrode 150, source electrode 171, and drain electrode 172 as a mask. The portion of the gate insulating layer 140 that is not protected by the gate electrode 150, source electrode 171, and drain electrode 172 is removed by etching.

In the process of selectively etching the gate insulating layer 140, the active layer 130 may be selectively conductorized.

During the selective etching process for the gate insulating layer 140, areas of the active layer 130 that overlap the gate electrode 150, the first conductive pattern 175, and the second conductive pattern 176 are protected by the gate electrode 150, the first conductive pattern 175 and the second conductive pattern 176, and are not conductorized.

Areas of the active layer 130 that are not protected by the gate electrode 150, the first conductive pattern 175, and the second conductive pattern 176 may be conductorized during the selective etching process for the gate insulating layer 140. As a result, the second part 130a2 of the first connection portion 130a and the second part 130b2 of the second connection portion 130b can be conductorized.

Next, referring to FIG. 16F, the interlayer insulating film 180 is disposed on the gate electrode 150, source electrode 171, and drain electrode 172. As a result, the thin film transistor 1500 according to another embodiment of the present disclosure can be completed.

Hereinafter, a display apparatus according to another embodiment of the present disclosure will be described. A display apparatus according to another embodiment of the present disclosure includes a substrate 110 and a thin film transistor 100, 200, 300, 400, 500, 600, 700, 800, 900, 1000, 1100, 1200, 1300, 1400, 1401, 1402, 1403, 1405, 1500 disposed on the substrate 110.

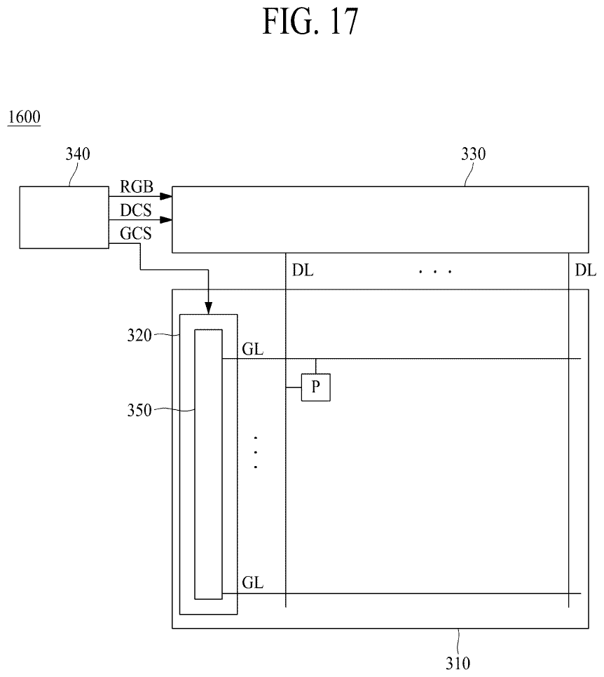

FIG. 17 is a schematic diagram of a display apparatus 1600 according to another embodiment of the present disclosure.

The display apparatus 1600 according to another embodiment of the present disclosure includes a display panel 310, a gate driver 320, a data driver 330, and a controller 340, as shown in FIG. 17.

Gate lines GL and data lines DL are disposed on the display panel 310, and pixels P are disposed in intersection areas of the gate lines GL and data lines DL. Images are displayed in the display panel 310 by driving pixels P.

The controller 340 controls the gate driver 320 and data driver 330.

The controller 340 uses a signal supplied from an external system (not shown) to generate a gate control signal GCS to control the gate driver 320 and a data control signal DCS to control the data driver 330. outputs. In addition, the controller 340 samples input image data input from an external system, realigns it, and supplies the rearranged digital image data (RGB) to the data driver 330.

The gate control signal GCS includes a gate start pulse GSP, gate shift clock GSC, gate output enable signal GOE, start signal Vst, and gate clock GCLK. In addition, the gate control signal GCS may include control signals for controlling the shift register.

The data control signal DCS includes a source start pulse SSP, source shift clock signal SSC, source output enable signal SOE, and polarity control signal POL.

The data driver 330 supplies data voltage to the data lines DL of the display panel 310. In detail, the data driver 330 converts the image data RGB input from the controller 340 into an analog data voltage and supplies the data voltage to the data lines DL.

According to one embodiment of the present disclosure, the gate driver 320 may be disposed on the substrate 110. The gate driver 320 may include a shift register 350.

The shift register 350 sequentially supplies gate pulses to the gate lines GL for one frame by using a start signal and gate clock transmitted from the controller 340. In this case, one frame means a time period during which one image is output through the display panel 310. The gate pulse has a turn-on voltage that can turn on the switching element (thin film transistor) disposed in the pixel P.

Also, the shift register 350 supplies a gate-off signal capable of turning off the switching element to the gate line GL during the remaining period of the one frame in which the gate pulse is not supplied. Hereinafter, the gate pulse and gate off signal are collectively referred to as a scan signal (SS or Scan).

According to one embodiment of the present disclosure, the gate driver 320 may be mounted on the display panel 310. In this way, the structure in which the gate driver 320 is directly mounted on the display panel 310 is called a gate in panel (GIP) structure.

The gate driver 320 may include a plurality of thin film transistors. A plurality of thin film transistors included in the gate driver 320 may be disposed in the shift register 350.

According to another embodiment of the present disclosure, the gate driver 320 may include at least one of the above described thin film transistors 100, 200, 300, 400, 500, 600, 700, 800, 900, 1000, 1100, 1200, 1300, 1400, 1401, 1402, 1403, 1405, 1500). The thin film transistor disposed in the gate driver 320 may have the same structure as at least one of the thin film transistor 100, 200, 300, 400, 500, 600, 700, 800, 900, 1000, 1100, 1200, 1300, 1400, 1401, 1402, 1403, 1405, 1500 described above.

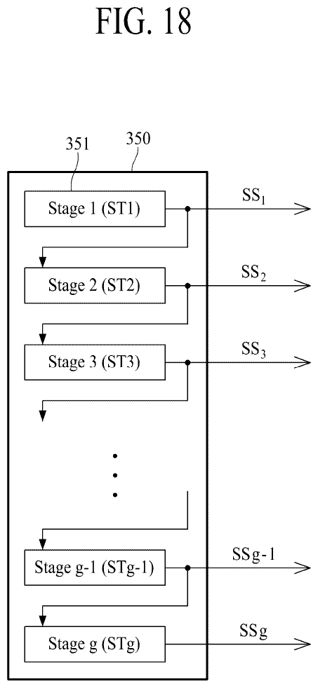

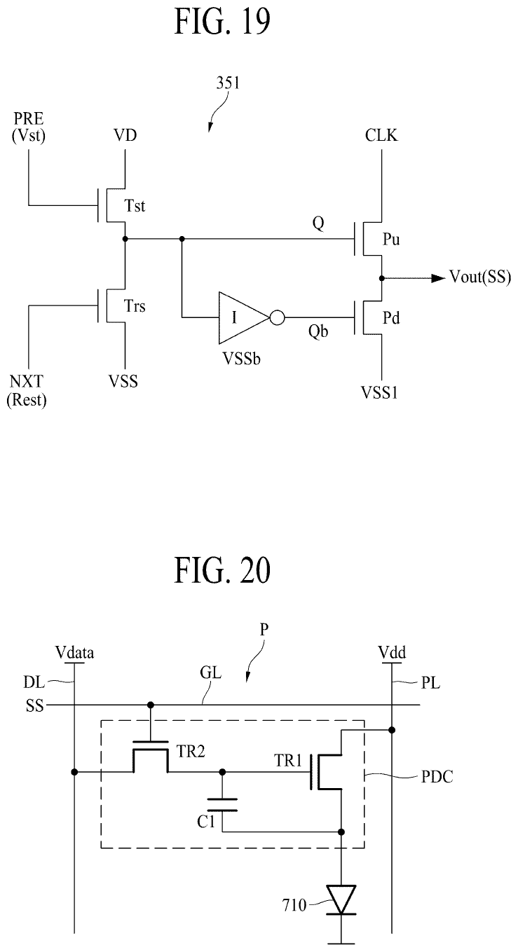

FIG. 18 is a schematic diagram of a shift register 350. FIG. 19 is a circuit diagram of an embodiment of the stage 351 provided in the shift register 350 of FIG. 18.

Referring to FIG. 18, the shift register 350 may include number g of stages 351 (STI to STg).

The shift register 350 transmits one scan signal SS to the pixels P connected to one gate line GL through one gate line GL. Each of the stages 351 may be connected to one gate line GL. When n gate lines (GL) are formed in the display panel 310, the shift register 350 may include g stages 351 (STI to STg) and g scan signals (SSI to SSg) can be generated.

In general, each stage 351 outputs the gate pulse GP once per frame, and the gate pulses GP are sequentially output from each stage 351.

As shown in FIG. 19, each of the stages 351 that sequentially output the gate pulse GP includes a pull-up transistor Pu, a pull-down transistor Pd, a start transistor Tst, a reset transistor Trs, and an inverter I. The above-described thin film transistors 100, 200, 300, 400, 500, 600, 700, 800, 900, 1000, 1100, 1200, 1300, 1400, 1401, 1402, 1403, 1405, 1500 can be applied to a pull-up transistor Pu, a pull-down transistor Pd, a start transistor Tst, and a reset transistor Trs, respectively.

The pull-up transistor Pu is turned on or off depending on the logic state of the Q node, and when turned on, it receives a clock signal CLK and outputs a gate pulse GP [Vout (SS)].

The pull-down transistor Pd is connected between the pull-up transistor Pu and the turn-off voltage VSS1, and turns off when the pull-up transistor Pu is turned on, and turns on when the pull-up transistor Pu turns off and outputs an gate off signal Goff.

In this way, the output Vout of the stage 351 includes the gate pulse GP and the gate off signal Goff. The gate pulse GP may have a high level voltage, and the gate off signal Goff may have a low level voltage.

The start transistor Tst charges the Q node with a high level voltage VD in response to the previous output PRE from the previous stage. When the stage 351 is the first stage STI, a start pulse Vst is supplied instead of the previous output PRE.

The reset transistor Trs discharges the Q node to the low potential voltage VSS, which is a reset voltage, in response to the rear output NXT from the next stage. When the stage 351 is the last stage STg, a reset pulse Rest is supplied instead of the rear output NXT.

The control signal input to the gate terminal of the reset transistor Trs generally maintains a low state when the Q node is high.

When a high level signal is input to the Q node, the pull-up transistor Pu is turned on and a gate pulse GP is output. At this time, the reset transistor Trs must be turned off so that the low potential voltage VSS is not supplied to the reset transistor Trs.

When the gate pulse GP is output, a high level control signal is input to the gate terminal of the reset transistor Trs, the reset transistor Trs is turned on, and the pull-up transistor Pu is turned off. As a result, the gate pulse GP is not output through the pull-up transistor Pu.

The inverter I performs a function of transmitting a Qb node control signal for generating a gate off signal Goff to the pull-down transistor Pd through the Qb node when the gate pulse GP is not generated.

Due to the turn-on voltage that can turn on the switching elements of each pixel P connected to the gate line GL, the data voltage is output to the data lines DL every horizontal period. During the remaining periods except for one horizontal period in one frame, the gate off signal (Goff) to maintain the switching element in the turn-off state is typically output to the gate line GL.

To this end, the inverter I transmits the Qb node control signal to the pull-down transistor Pd through the Qb node during the remaining period except for one horizontal period in one frame.

By the Qb node control signal supplied from the inverter I, the pull-down transistor Pd is turned on, and the gate-off signal Goff is output to the gate line GL.

FIG. 20 is a circuit diagram of a pixel P of FIG. 17.

The circuit diagram of FIG. 20 is an equivalent circuit diagram of a pixel P of a display apparatus 1600 including an organic light emitting diode OLED as the display element 710. The pixel P includes a display element 710 and a pixel driving circuit PDC that drives the display element 710. In some embodiments, the organic light emitting diode OLED (or 710) is on the substrate 110 and electrically connected to a thin film transistor described in conjunction with FIGS. 1 to 16.

According to another embodiment of the present disclosure, the display apparatus 1600 includes a pixel driving circuit PDC disposed on the substrate 110. The pixel driving circuit PDC may include at least one of the above described thin film transistor 100, 200, 300, 400, 500, 600, 700, 800, 900, 1000, 1100, 1200, 1300, 1400, 1401, 1402, 1403, 1405, 1500.

Referring to FIG. 20, the pixel driving circuit PDC includes a first thin film transistor TR1 and a second thin film transistor TR2. As at least one of the first thin film transistor TR1 and the second thin film transistor TR2, at least one of the above described thin film transistor 100, 200, 300, 400, 500, 600, 700, 800, 900, 1000, 1100, 1200, 1300, 1400, 1401, 1402, 1403, 1405, 1500 may be used.

According to another embodiment of the present disclosure, the first thin film transistor TR1 is a driving transistor, and the second thin film transistor TR2 is a switching transistor.

The second thin film transistor TR2 is connected to the gate line GL and the data line DL, and is turned on or turned off by the scan signal SS supplied through the gate line GL.

The data line DL provides the data voltage Vdata to the pixel driving circuit PDC, and the second thin film transistor TR2 controls the application of the data voltage Vdata.

The driving power line PL provides a driving voltage Vdd to the display element 710, and the first thin film transistor TR1 controls the driving voltage Vdd. The driving voltage Vdd is a pixel driving voltage for driving an organic light emitting diode OLED, which is the display element 710.

When the second thin film transistor TR2 is turned on by the scan signal SS applied from the gate driver 320 through the gate line GL, the data voltage Vdata supplied from the data line DL is supplied to the gate electrode of the first thin film transistor TR1 connected to the display element 710. The data voltage Vdata is charged in the storage capacitor C1 formed between the gate electrode and the source electrode of the first thin film transistor TR1.

The amount of current supplied to the organic light emitting diode OLED, which is the display element 710, through the first thin film transistor TR1 is controlled according to the data voltage Vdata, whereby gray scale light emitted from the display element 710 is controlled.

According to another embodiment of the present disclosure, the first thin film transistor TR1 and the second thin film transistor TR2 are disposed on the substrate 110.

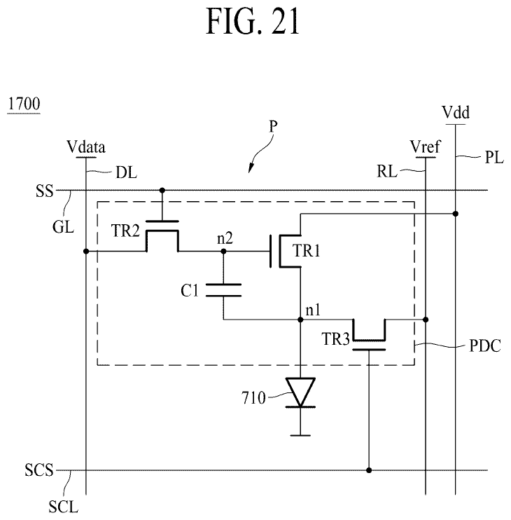

FIG. 21 is a circuit diagram of a pixel P of a display apparatus 1700 according to another embodiment of the present disclosure.

FIG. 21 is an equivalent circuit diagram for a pixel P of an organic light emitting display apparatus.

The pixel P of the display apparatus 1700 shown in FIG. 21 includes an organic light emitting diode OLED, which is the display element 710, and a pixel driving circuit PDC to drive the display element 710. The display element 710 is connected to a pixel driving circuit PDC.

In the pixel P, signal lines DL, GL, PL, RL, and SCL that supply signals to the pixel driving circuit PDC are disposed.

A data voltage Vdata is supplied to the data line DL, a scan signal SS is supplied to the gate line GL, a driving voltage Vdd for driving the pixel is supplied to the driving power line PL, a reference voltage Vref is supplied to the reference line RL, and a sensing control signal SCS is supplied to the sensing control line SCL.

The pixel driving circuit PDC, for example, includes a second thin film transistor TR2 (switching transistor) connected with the gate line GL and the data line DL, a first thin film transistor TR1 (driving transistor) for controlling a magnitude of a current output to the display element 710 in accordance with the data voltage Vdata transmitted through the second thin film transistor TR2, and a third thin film transistor TR3 (reference transistor) for sensing characteristics of the first thin film transistor TR1.

The storage capacitor C1 is located between the gate electrode of the first thin film transistor TR1 and the display element 710.

The second thin film transistor TR2 is turned on by the scan signal SS supplied to the gate line GL, and transmits the data voltage Vdata, which is supplied to the data line DL, to the gate electrode of the first thin film transistor TR1.

The third thin film transistor TR3 is connected to a first node n1 between the first thin film transistor TR1 and the display element 710 and the reference line RL, and turned on or turned off by the sensing control signal SCS, and senses characteristics of the first thin film transistor TR1, which is a driving transistor, during a sensing period.

The second node n2 connected to the gate electrode of the first thin film transistor TR1 is connected to the second thin film transistor TR2. A storage capacitor C1 is formed between the second node n2 and the first node n1.

When the second thin film transistor TR2 is turned on, the data voltage Vdata supplied through the data line DL is supplied to the gate electrode of the first thin film transistor TR1. The data voltage Vdata is charged in the storage capacitor C1 formed between the gate electrode and the source electrode of the first thin film transistor TR1.

When the first thin film transistor TR1 is turned on, current is supplied to the display element 710 through the first thin film transistor TR1 by the driving voltage Vdd that drives the pixel, and light is emitted from the display element 710.

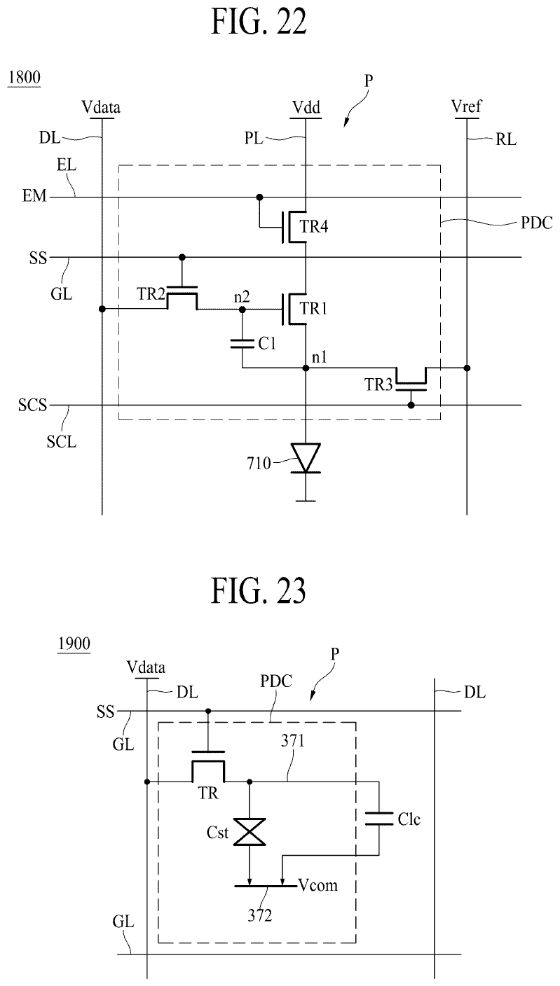

FIG. 22 is a circuit diagram of a pixel of a display apparatus 1800 according to another embodiment of the present disclosure.

The pixel P of the display apparatus 1800 shown in FIG. 22 includes an organic light emitting diode OLED, which is the display element 710, and a pixel driving circuit PDC to drive the display element 710. The display element 710 is connected to a pixel driving circuit PDC.

The pixel driving circuit PDC includes thin film transistors TR1, TR2, TR3, and TR4.

In the pixel P, signal lines DL, EL, GL, PL, SCL, and RL that supply signals to the pixel driving circuit PDC are disposed.

Compared to the pixel P of FIG. 21, the pixel P of FIG. 22 further includes an emission control line EL. An emission control signal EM is supplied to the emission control line EL.

In addition, compared to the pixel driving circuit PDC of FIG. 21, the pixel driving circuit PDC of FIG. 22 further includes a fourth thin film transistor TR4, which is an emission control transistor for controlling the timing of light emission of the first thin film transistor TR1.

A storage capacitor C1 is positioned between the gate electrode of the first thin film transistor TR1 and the display element 710.

The second thin film transistor TR2 is turned on by the scan signal SS supplied to the gate line GL, and transmits the data voltage Vdata, which is supplied to the data line DL, to the gate electrode of the first thin film transistor TR1.

The third thin film transistor TR3 is connected to the reference line RL, is turned on or turned off by the sensing control signal SCS, and senses the characteristics of the first thin film transistor TR1, which is a driving transistor, during the sensing period.

The fourth thin film transistor TR4 transfers the driving voltage Vdd to the first thin film transistor TR1 or blocks the driving voltage Vdd according to the emission control signal EM. When the fourth thin film transistor TR4 is turned on, current is supplied to the first thin film transistor TR1, whereby light is emitted from the display element 710.

The pixel driving circuit PDC according to another embodiment of the present disclosure may be formed in various structures other than those described above. The pixel driving circuit PDC may include, for example, five or more thin film transistors.

FIG. 23 is a circuit diagram of a pixel of a display apparatus 1900 according to another embodiment of the present disclosure.

The pixel P of the display apparatus 1900 shown in FIG. 23 includes a pixel driving circuit PDC and a liquid crystal capacitor Clc connected to the pixel driving circuit PDC. The liquid crystal capacitor Clc corresponds to a display element. The display apparatus 1900 of FIG. 23 is a liquid crystal display apparatus.

The pixel driving circuit PDC includes a thin film transistor TR connected to the gate line GL and the data line DL, a pixel electrode 371 connected to the thin film transistor TR, a common electrode 372 opposing the pixel electrode 371, and a storage capacitor Cst connected between the thin film transistor TR and the common electrode 372. The liquid crystal capacitor Clc is connected in parallel with the storage capacitor Cst between the thin film transistor TR and the common electrode 372.

The liquid crystal capacitor (Clc) charges voltage difference between the data voltage Vdata supplied to the pixel electrode 371 through the thin film transistor (TR) and the common voltage Vcom supplied to the common electrode 372, and drives liquid crystal according to the charged voltage to control the amount of light transmission. The storage capacitor Cst maintains the voltage charged in the liquid crystal capacitor Clc stable.

The display apparatus 1900 according to another embodiment of the present disclosure may include at least one of the above described thin film transistor 100, 200, 300, 400, 500, 600, 700, 800, 900, 1000, 1100, 1200, 1300, 1400, 1401, 1402, 1403, 1405, 1500.

The present disclosure described above is not limited to the above-described embodiments and the accompanying drawings, and it is well known to those with ordinary knowledge that various substitutions, modifications, and changes are possible within the scope of the technical details of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
an active layer on a light shielding layer;
a gate electrode spaced apart from the active layer and overlapping at least a portion of the active layer; and
an internal bridge electrically connecting the gate electrode and the light shielding layer;
wherein the active layer comprises:
a channel portion overlapping the gate electrode;
a first connection portion contacting one side of the channel portion, the first connection portion not overlapping the gate electrode; and
a second connection portion spaced apart from the first connection portion and contacting the other side of the channel portion, second connection portion not overlapping the gate electrode,
wherein the light shielding layer overlaps at least the entire channel portion, and
the internal bridge overlaps the gate electrode and penetrates the active layer along a direction from the gate electrode to the light shielding layer.

2. The thin film transistor according to claim 1, further comprising
a buffer layer between the light shielding layer and the active layer; and
a gate insulating layer between the active layer and the gate electrode,
wherein the internal bridge is insulated from the active layer and penetrates the gate insulating layer and the buffer layer.

3. The thin film transistor according to claim 1,
wherein the internal bridge contacts the gate electrode and the light shielding layer.

4. The thin film transistor according to claim 1,
wherein the internal bridge is integrated with the gate electrode.

5. The thin film transistor according to claim 1,
wherein an active hole is disposed in an area whose boundary is defined by the active layer, and the active layer is not disposed in the active hole,
wherein at least a portion of the active hole overlaps the gate electrode, and
the internal bridge is disposed in the active hole in a planar view.

6. The thin film transistor according to claim 5,
wherein the active hole as a whole overlaps the gate electrode.

7. The thin film transistor according to claim 5,
wherein a portion of the active hole does not overlap the gate electrode.

8. The thin film transistor according to claim 5,
wherein the active hole includes a first active hole and a second active hole spaced apart from each other, and
at least a portion of the first active hole and at least a portion of the second active hole overlap the gate electrode.

9. The thin film transistor according to claim 8, wherein the internal bridge comprises:
a first internal bridge disposed in the first active hole; and
a second internal bridge disposed in the second active hole.

10. The thin film transistor according to claim 9,
wherein the first active hole and the second active hole are disposed to be spaced apart from each other along a direction perpendicular to a direction connecting the first connection portion and the second connection portion.

11. The thin film transistor according to claim 9,
wherein the first active hole and the second active hole are disposed to be spaced apart from each other along a direction connecting the first connection portion and the second connection portion.

12. The thin film transistor according to claim 5,
wherein a portion of the active hole protrudes from the gate electrode along a direction connecting the first connection portion and the second connection portion in a plan view.

13. The thin film transistor according to claim 12,
wherein the active hole protrudes at both sides of the gate electrode in a plan view.

14. The thin film transistor according to claim 1, further comprising
a first conductive pattern on the first connection portion; and
a second conductive pattern on the second connection portion, and
wherein the first conductive pattern and the second conductive pattern do not overlap the gate electrode.

15. The thin film transistor according to claim 1, further comprising:
an external bridge not penetrating the active layer and being disposed outside the area defined by the active layer,
wherein the external bridge overlaps the gate electrode and electrically connects the gate electrode and the light shielding layer.

16. The thin film transistor according to claim 1, further comprising:
at least one external bridge not extending through the active layer,
wherein the at least one external bridge does not overlap with the active layer from a plan view, and
wherein the at least one external bridge overlaps the gate electrode from a plan view and electrically connects the gate electrode and the light shielding layer.

17. A manufacturing method of a thin film transistor, the manufacturing method comprising:
forming a light shielding layer on a substrate;
forming a buffer layer on the light shielding layer;
forming an active layer on the buffer layer;
forming a gate insulating layer on the active layer; and
forming a gate electrode on the gate insulating layer,
wherein forming the active layer includes forming an active hole by selectively removing a portion of the active layer,
wherein the active hole is disposed in an area whose boundary is defined by the active layer,
wherein forming the gate insulating layer includes forming a through hole penetrating the gate insulating layer and the buffer layer,
wherein the through hole passes through the active hole, and
wherein forming of the gate electrode includes forming an internal bridge disposed in the through hole.

18. The manufacturing method according to claim 17,
wherein the internal bridge is in contact with the gate electrode and the light shielding layer.

19. A display apparatus comprising:
a light emitting diode on a substrate; and
a transistor electrically connected to the light emitting diode, the transistor including:
an active layer including a first hole;
a gate electrode spaced apart from the active layer;
a first internal bridge extending from the gate electrode and extending through the first hole of the active layer;
a source electrode and a drain electrode adjacent to the gate electrode.

20. The display apparatus of claim 19, further comprising:
a light shielding layer between the substrate and the active layer,
wherein the first internal bridge extending from the gate electrode electrically connects to the light shielding layer, and
wherein the light shielding layer fully overlaps a channel portion of the active layer from a plan view.

21. The display apparatus of claim 19, wherein the first internal bridge is integrated with the gate electrode such that the first internal bridge and the gate electrode are a single, continuous structure.

22. The display apparatus of claim 19, further comprising:
a second internal bridge extending from the gate electrode, the second internal bridge being different from the first internal bridge,
wherein the active layer further includes a second hole at a different location from the first hole from a plan view,
wherein the second internal bridge extends through the second hole of the active layer.

23. The display apparatus according to claim 19, further comprising:
a gate driver on the substrate,
wherein the gate driver includes the transistor.

24. The display apparatus according to claim 19, further comprising:
a pixel driving circuit on the substrate,
wherein the pixel driving circuit includes the transistor.
